(19) United States
(12) Patent Application Publication
(10) Pub. No.: US 2025/0254978 A1
(43) Pub. Date: Aug. 7, 2025

(54) Front-End-Of-Line (FEOL) and Middle-of-Line (MOL) of Planar SCMOS Fabrication Processes

(71) Applicant: SCHOTTKY LSI, INC., Los Altos Hill, CA (US)

(72) Inventor: Pierre Dermy, Los Altos Hills, CA (US)

(21) Appl. No.: 19/084,612

(22) Filed: Mar. 19, 2025

Related U.S. Application Data
(63) Continuation of application No. PCT/US23/33154, filed on Sep. 19, 2023.
(60) Provisional application No. 63/408,796, filed on Sep. 21, 2022.
(60) Provisional application No. 63/494,362, filed on Apr. 5, 2023.
(60) Provisional application No. 63/509,250, filed on Jun. 20, 2023.

(51) Int. Cl. H10D 84/00; H10D 62/60; H10D 64/66

(52) U.S. Cl. CPC H10D 84/156; H10D 62/60; H10D 64/668

(57) ABSTRACT

This application is directed to integrating metal oxide semiconductor (MOS) transistors and Schottky barrier diodes (SBDs). An integrated planar semiconductor device includes a substrate, an SBD joining an SBD semiconductor and a barrier metal on the substrate, and a MOS transistor formed on the substrate and including a gate, a source, and a drain. A portion of the gate of the MOS transistor extends from the MOS transistor to the SBD and is in contact with the SBD semiconductor. In some implementations, the drain of the MOS transistor includes an extended drain structure. The SBD semiconductor includes a first semiconductor portion and a second semiconductor portion. A doping profile of the extended drain structure is substantially the same as that of the second semiconductor portion. A doping concentration of a channel region of the MOS transistor is substantially the same as that of the first semiconductor portion.

### RELATED APPLICATIONS

This application is a continuation of and claims benefits to International Patent Application No. PCT/US2023/033154, filed Sep. 19, 2023, titled “Integration of Field Effect Transistors and Schottky Diodes on a Substrate,” which claims priority to U.S. Provisional Application No. 63/408,796, filed Sep. 21, 2022, titled “Integration of Field Effect Transistors and Schottky Diodes on a Substrate,” U.S. Provisional Application No. 63/494,362, filed Apr. 5, 2023, titled “Front-End-Of-Line (FEOL) and Middle-of-Line (MOL) of Planar SCMOS Fabrication Processes,” and U.S. Provisional Application No. 63/509,250, filed Jun. 20, 2023, titled “Front-End-Of-Line (FEOL) and Middle-of-Line (MOL) of Planar SCMOS Fabrication Processes.” Each of these applications is incorporated by reference in its entirety.

### TECHNICAL FIELD

This application relates generally to integrated circuit (IC) devices, and more particularly to devices and methods for integrating field effect transistors (FETs) and Schottky barrier diodes (SBDs) on a semiconductor substrate.

### BACKGROUND

Various sectors of high technology industries have been driven by a sustained increase in device density of integrated circuits (IC's) during the past few decades. These high technology industries include semiconductor, electronics, computer, communication as well as their associated software fields for establishing system platforms and software applications. This increase in device density of the ICs has been made possible primarily by new photolithography techniques using shorter light wavelengths and/or by chemical and physical manufacturing processes having a desirable production yield, reproducibility, and quality control.

IC development has experienced multiple technology nodes corresponding to different semiconductor manufacturing process, design rules, circuit generations, and/or system architectures. Each technology node is achieved by reducing sizes of the ICs, improving performance of metal-oxide-semiconductor field-effect transistor (MOSFET), and increasing levels and densities of metal interconnections. Each new technology node is thereby more complex than a previous technology node, requiring more expensive microfabrication techniques, facilities and resources. Tools, time and manpower applied to implement very large scale integrated (VLSI) circuits also become more complex and costly at each new technology node. Prior to a 20 nm technology node, MOSFETs are integrated on a substrate with planar structures, and beyond the 20 nm technology node, MOSFETs start to adopt three-dimensional (3D) structures, adding a height to its channel width and allowing a shorter channel length. However, deployment of technology nodes have been focused on MOSFETs involving little or no other active semiconductor devices (e.g., a diode). It would be beneficial to engage different type of semiconductor devices into the integrated circuit than the current practice.

### SUMMARY

This application is directed to integrating planar field-effect transistors (FET) and Schottky barrier diodes (SBDs) on a substrate in a monolithic manner (e.g., via a planar semiconductor microfabrication process). Specifically, this application describes an overall IC manufacturing method of P-type and N-type SBDs. These SBDs are used with P-type and N-type MOSFETs (e.g., PMOS and NMOS transistors) that are offered in an existing or upcoming planar complementary metal-oxide-semiconductor (CMOS) technology node of large scale industrial production, thereby implementing Schottky-based complementary metal-oxide-semiconductor (SCMOS) ICs. Each portion of an SBD is formed from existing semiconductor manufacturing operations of the semiconductor microfabrication process without adding any masks, and therefore, corresponds to a respective portion of a FET.

In various embodiments of this application, a portion of a gate of a metal oxide semiconductor (MOS) transistor extends from the MOS transistor to an SBD and is in contact with an SBD semiconductor of the SBD. In some implementations, the portion of the gate of the MOS transistor extends from the MOS transistor to the SBD along a first direction perpendicular to a second direction. The source, gate, and drain of the MOS transistor are arranged along the second direction, and both the first and second directions are parallel to a surface of the substrate. A front-end-of-line (FEOL) is the first portion of IC fabrication where the individual components (e.g., transistors, SBDs) are patterned on a substrate, and a middle-of-line (MOL) of IC fabrication connects the separate transistor and interconnect pieces using a series of contact structures.

In one aspect of the application, a method is implemented to form an integrated planar semiconductor device. The method includes forming a Schottky barrier diode (SBD) on a substrate. The SBD joins an SBD semiconductor and a barrier metal. The method further includes forming a source and a drain of a metal oxide semiconductor (MOS) transistor on the substrate and forming a gate of the MOS transistor. A portion of the gate of the MOS transistor extending from the MOS transistor to the SBD and being in contact with the SBD semiconductor.

In another aspect, an integrated planar semiconductor device includes a substrate, a Schottky barrier diode (SBD) joining an SBD semiconductor and a barrier metal on the substrate, and a metal oxide semiconductor (MOS) transistor formed on the substrate and including a gate, a source, and a drain. A portion of the gate of the MOS transistor extends from the MOS transistor to the SBD and is in contact with the SBD semiconductor.

In some embodiments, the SBD includes an N-type SBD, and the SBD semiconductor includes an N-type semiconductor material. The MOS transistor includes a P-type MOS (PMOS) transistor. The SBD and MOS transistors are located in a P-well and an N-well, respectively. Alternatively, in some embodiments, the SBD includes an P-type SBD, and the SBD semiconductor includes an P-type semiconductor material. The MOS transistor includes an N-type MOS (NMOS) transistor. The SBD and MOS transistors are located in an N-well and a P-well, respectively. Alternatively, in some embodiments, the SBD includes an N-type SBD, and the SBD semiconductor includes an N-type semiconductor material. The MOS transistor includes an N-type MOS (NMOS) transistor. The N-type SBD and NMOS transistors are located in the same P-well. Alternatively, in some embodiments, the SBD includes an P-type SBD, and the SBD semiconductor includes a P-type semiconductor material. The MOS transistor includes an P-type MOS (PMOS) transistor. The P-type SBD and PMOS transistors are located in the same N-well.

These illustrative embodiments and implementations are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described implementations, reference should be made to the Description of Embodiments below, in conjunction with the following drawings in which like reference numerals refer to corresponding parts throughout the figures.

FIG. 1A is a schematic diagram of a three-input Schottky CMOS NAND logic gate integrating CMOS transistors and Schottky barrier diodes, in accordance with some implementations.

FIG. 1B is an IC layout diagram of a three-input NAND logic gate shown in FIG. 1A, in accordance with some implementations.

FIG. 2A is a first cross-sectional view of an integrated planar semiconductor device that includes CMOS transistors (e.g., PMOS transistor) and complementary SBDs (e.g., N-type SBD), in accordance with some implementations.

FIG. 2B is a second cross-sectional view of an integrated planar semiconductor device that includes CMOS transistors (e.g., NMOS transistor) and complementary SBDs (e.g., P-type SBD), in accordance with some implementations.

FIG. 2C is a third cross-sectional view of an integrated planar semiconductor device that includes CMOS transistors (e.g., PMOS transistor) and complementary SBDs (e.g., P-type SBD), in accordance with some implementations.

FIG. 2D is a fourth cross-sectional view of an example integrated planar semiconductor device 200 that includes CMOS transistors (e.g., NMOS transistor) and complementary SBDs (e.g., N-type SBD), in accordance with some implementations.

FIGS. 3A and 3B are two distinct cross-sectional views of an example integrated semiconductor device including a PMOS transistor and an N-type SBD in accordance with some implementations.

FIGS. 3C and 3D are two distinct cross-sectional views of an example integrated semiconductor device including an NMOS transistor and a P-type SBD, in accordance with some implementations.

FIGS. 4A and 4B are two distinct cross-sectional views of another example integrated semiconductor device including an NMOS transistor and an N-type SBD in a P-well, in accordance with some implementations.

FIGS. 4C and 4D are two distinct cross-sectional views of another example integrated semiconductor device including a PMOS transistor and a P-type SBD in an N-well, in accordance with some implementations.

FIGS. 4E and 4F are cross-sectional views of two example integrated semiconductor devices each including an NMOS transistor and an N-type SBD in a P-well, in accordance with some implementations.

FIGS. 4G and 4H are cross-sectional views of example integrated semiconductor devices each including a PMOS transistor and a P-type SBD in an N-well, in accordance with some implementations.

FIG. 5A is a cross-sectional view of an example integrated semiconductor device including a PMOS transistor and an N-type SBD in accordance with some implementations.

FIG. 5B is a cross-sectional view of an example integrated semiconductor device including an NMOS transistor and a P-type SBD, in accordance with some implementations.

FIG. 5C is a cross-sectional view of another example integrated semiconductor device including an NMOS transistor and an N-type SBD in a P-well, in accordance with some implementations.

FIG. 5D is a cross-sectional view of another example integrated semiconductor device including a PMOS transistor and a P-type SBD in an N-well 216, in accordance with some implementations.

FIGS. 6A and 6B are two distinct cross-sectional views of an integrated semiconductor device that includes CMOS transistors and complementary SBDs and is processed to a first metallic layer in an MOL, in accordance with some implementations.

FIG. 7 is a flow diagram of a method of forming an integrated planar semiconductor device, in accordance with some implementations.

Like reference numerals refer to corresponding parts throughout the several views of the drawings.

### DESCRIPTION OF EMBODIMENTS

This application is directed to a Schottky-based complementary metal oxide semiconductor (SCMOS) technology that integrates P-type and N-type Schottky barrier diodes (SBDs) in a planar CMOS microfabrication process. Each SBD is made by joining a barrier metal and a semiconductor structure. Its electrcial behavior results from the electronic properties at the interface between these two materials. The proper operation of the SBD's is very sensitive to the composition of this structure and its surface. Various methods of surface preparation are used to control the SBD electrical characteristics. They typically include surface oxidation and cleaning steps, the introduction of impurity atoms at the surface as well as deep into the semiconductor structure prior to or after the deposition of the barrier metal (e.g., Ni/Co/Ti/Pt). The barrier metal is depositied on the desired areas of the surface selected by photolithography. The barrier metal may also be doped with impurity atoms prior to its deposition. In the case of a silicon surface, the barrier metal is usually silicided by a heating cycle, which has little effect on the electrical properties of the other semiconductor devices, mostly MOSFET's. In other semiconductor process cases, the barrier metal may not undergo this chemical reaction with the silicon surface. A pure barrier metal film may produce the desired electrical characteristics following a proper surface preparation. Also, an alternative method is to deposit the silicide compound of the barrier metal, either directly as the source material of this deposition or by a chemical reaction in-situ of the metal deposition chamber to produce it. Impurity atoms may be mixed into this source, instead of or in addition to a doping step after the deposition. Even though complicated, the formation of SBD's on various semiconductor structures is well developed. The physics and chemistry of producing SBD's are well understood. However, in cases of CMOS integrated circuits made on a silicon substrate, until the present invention, SBD's are commonly built in a Well of a CMOS integrated circuit. The most common Well is of type N-. However, it may be lso P-type. The technology advancement of this invention is to build and use SBD's formed on diffusion tubs of transistors and possibly other devices, rather than on P-/N-Wells (e.g., which may be shared with sources and drains of CMOS transistors or in their own individual tubs, whereas these tubs are used to build other semiconductor devices). Specifically, examples of the barrier metal include, but are not limited to, Nickel Silicide (NiSi/NiSi₂) or Cobalt Silicide (CoSi₂). Other materials are optionally applied as the barrier metal when a surface is shallowly doped with impurity atoms of metal materials or coated with a thin layer of metal material (e.g., Nickel, Nickel Silicide, Cobalt, Cobalt Silicide, and the like). The silicided diffusion tub is formed concurrently with sources and drains of CMOS transistors. In some implementations, a photomask is adjusted to block or insert certain ions implanted in the silicided diffusion tubs of the SBDs. In an example, tub serial resistance is reduced to increase a diode current density.

Each SBD has electrical conduction characteristics that are determined by material compositions of the barrier metal and silicided diffusion tub, and more specifically, by impurity and physical properties of a metal-to-silicon interface at a diode junction of the SBD. Example electronic properties of this metal-to-silicon interface include, but are not limited to, a barrier height, which is associated with a turn-on/turn-off voltage of the SBD. In some implementations, a combination of the barrier metal and silicided diffusion tub results in relatively low values of the barrier height and the turn-on/off voltage of the Schottky barrier diode, compared to a threshold voltage of the MOSFETs integrated in the SCMOS technology. Thus, the Schottky barrier diode having a lower turn-on/off voltage is also called a low-threshold Schottky barrier diodes (LtSBDs).

In some implementations, integration of the SBDs in a planar CMOS fabrication process (e.g., a in 28 nm or 65 nm technology node) is enabled by modifying a self-aligned silicidation module. A corresponding silicide defining photomask is involved in defining the SBDs. This photomask has a first critical dimension defining a feature size of the SBDs. In contrast, when it is used in a planar CMOS fabrication process involving no SBD, the silicide defining photomask has a second critical dimension (e.g., defining a feature size of a silicide resistor). The second critical dimension is greater than the first critical dimension associated with the SBDs. Although the silicide defining photomask is non-critical in the planar CMOS fabrication process, it becomes critical in the planar SCMOS fabrication process integrating the SBDs. A computer aided design (CAD) software tool is used to control a photomask making machine to print features of a circuit and device layout onto the silicide defining photomask according to logical formulas. Parameters applied in the logical formulas are modified to reflect a change of the critical dimension of the silicide defining photomask.

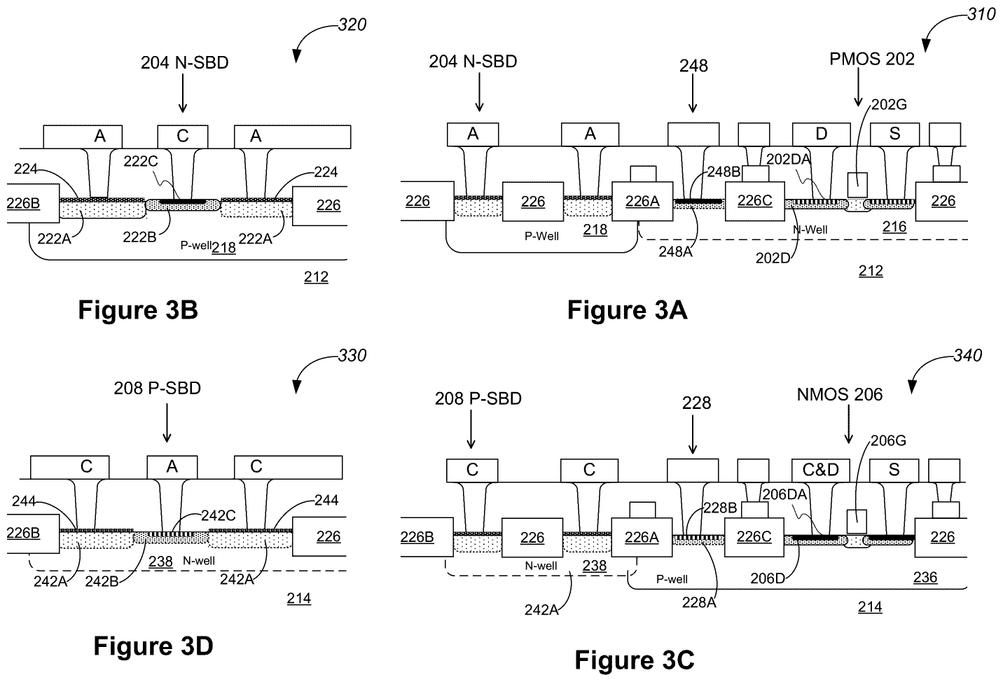

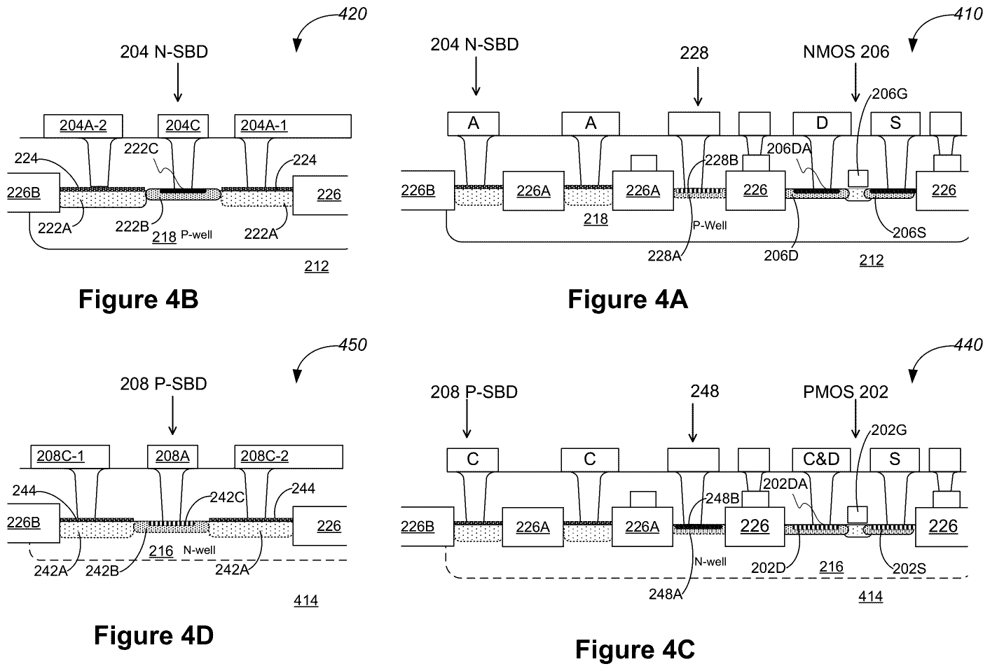

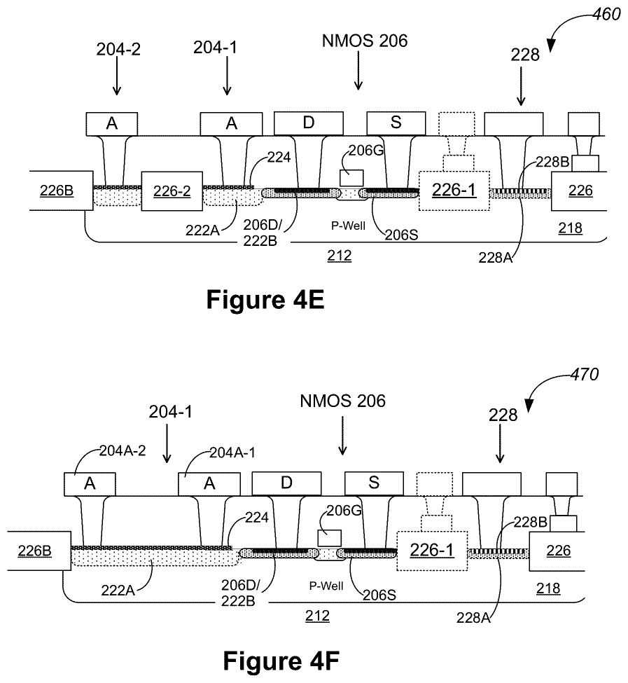

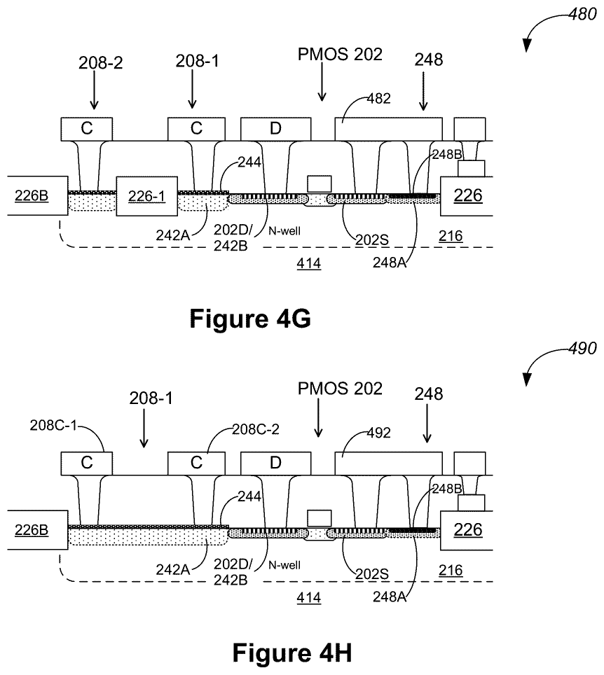

In some implementations, a MOS transistor is formed on the substrate and includes a gate, a source, and a drain. A portion of the gate of the MOS transistor extends from the MOS transistor to the SBD and is in contact with the SBD semiconductor. Further, in some embodiments (FIGS. 3A and 3B), the SBD includes an N-type SBD, and the SBD semiconductor includes an N-type semiconductor material. The MOS transistor includes a P-type MOS (PMOS) transistor. The SBD and MOS transistors are located in a P-well and an N-well that is optionally adjacent to the P-well, respectively. Alternatively, in some embodiments (FIGS. 3C and 3D), the SBD includes an P-type SBD, and the SBD semiconductor includes an P-type semiconductor material. The MOS transistor includes an N-type MOS (NMOS) transistor. The SBD and MOS transistors are located in an N-well and a P-well that is optionally adjacent to the N-well, respectively. Alternatively, in some embodiments (FIGS. 4A and 4B), the SBD includes an N-type SBD, and the SBD semiconductor includes an N-type semiconductor material. The MOS transistor includes an N-type MOS (NMOS) transistor. The N-type SBD and NMOS transistors are located in the same P-well. Alternatively, in some embodiments (FIGS. 4C and 4D), the SBD includes an P-type SBD, and the SBD semiconductor includes a P-type semiconductor material. The MOS transistor includes an P-type MOS (PMOS) transistor. The P-type SBD and PMOS transistors are located in the same N-well.

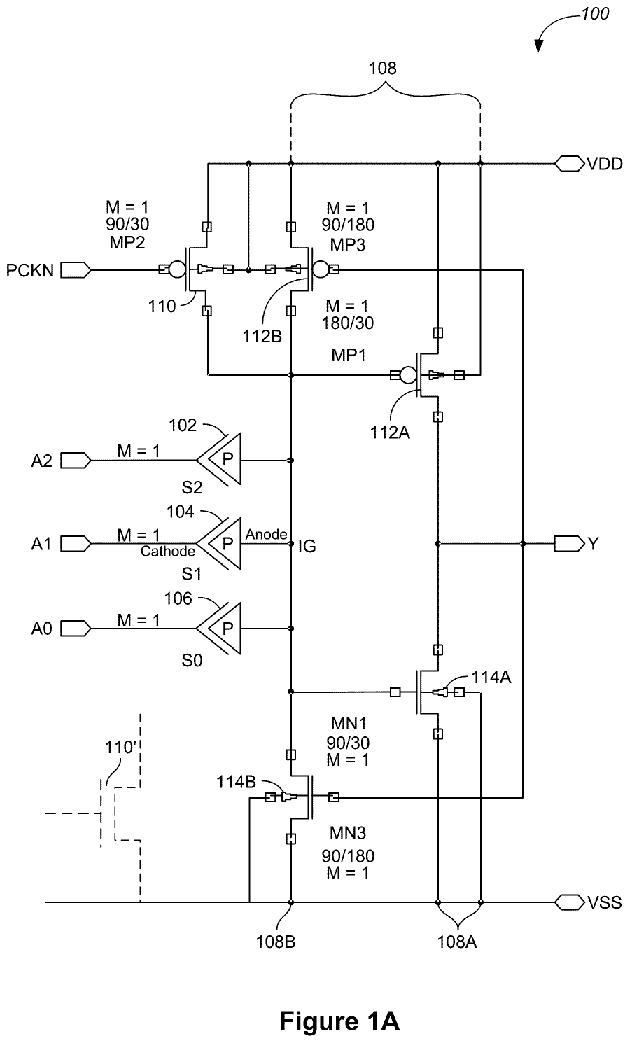

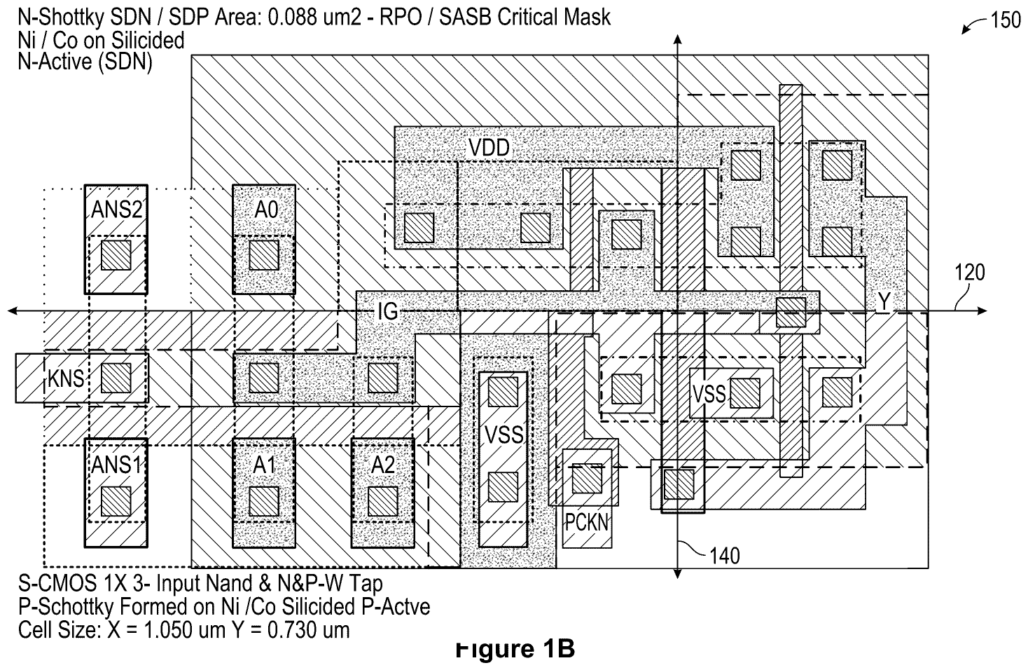

FIG. 1A is a schematic diagram of a three-input Schottky-CMOS NAND logic gate 100 integrating CMOS transistors and SBDs, in accordance with some implementations, and FIG. 1B is an IC layout diagram 150 of a three-input NAND logic gate shown in FIG. 1A, in accordance with some implementations. The three-input Schottky-CMOS NAND logic gate 100 includes three P-type SBDs 102, 104, and 106, a cross-coupled latch 108, and a control transistor 110. The cross-coupled latch 108 includes two CMOS inverters 108A and 108B, and an input and an output of the CMOS inverter 08A are cross-coupled to an output and an input of the CMOS inverter 108B, respectively. The CMOS inverter 108A includes a PMOS transistor 112A and an NMOS transistor 114A coupled in series with the PMOS transistor 112A. The CMOS inverter 108B includes a PMOS transistor 112B and an NMOS transistor 114B coupled in series with the PMOS transistor 112B. Input A0 is coupled to a cathode of p-type SBD 102. Input A1 is coupled to a cathode of p-type SBD 104. Input A2 is coupled to a cathode of p-type SBD 106. An anode of the SBD 102, an anode of the SBD 104, and an anode of the SBD 106 are coupled to each other. The anodes of the SBDs 102-106 are also coupled to the input of the CMOS inverter 108A (i.e., the gates of the PMOS transistor 112A and NMOS transistor 114A) and the output of the CMOS inverter 108B (i.e., the drains of the PMOS transistor 112B and NMOS transistor 114B). Conversely, an output Y of the NAND logic gate 100 is coupled to the output of the CMOS inverter 108A (i.e., the drains of the PMOS transistor 112A and NMOS transistor 114A) and the input of the CMOS inverter 108B (i.e., the gates of the PMOS transistor 112B and NMOS transistor 114B).

The CMOS inverters 108A and 108B are coupled between a high supply voltage VDD (e.g., 1.8V, 0.9V) and a low supply voltage VSS (e.g., ground, −1.8V). A source of the pull-up transistor 112A is coupled to the high supply voltage VDD, and a drain of the pull-up transistor 112B is coupled to the input of the CMOS inverter 108A and the anodes of the P-type SBDs 102-106. The control transistor 110 is controlled by an input signal PCKN. While the input signal PCKN is at the low supply voltage VSS, the input of the CMOS inverter 108A is at the high supply voltage VDD, and the output of the NAND logic gate 100 is the low supply voltage VSS. Conversely, while the input signal PCKN is at the high supply voltage VSS, the input of the CMOS inverter 108A is determined by a combination of the inputs A0, A1, and A2, so is the output of the NAND logic gate 100. As such, the NAND logic gate 100 is a dynamic logic controlled to be refreshed at a positive duty cycle of the input signal PCKN.

Referring to FIG. 1A, a Schottky-based CMOS implementation of the three-input NAND logic gate 100 uses the P-type control transistor 110 coupled to the anodes of the three SBDs 102-106. Conversely, in some implementations not shown, another Schottky-CMOS implementation of the three-input NAND logic gate uses an n-type transistor 100′ coupled to the anodes of the three SBDs 102-106 (replacing the PMOS control transistor 110). The N-type control transistor 110′ is coupled between the anodes of the three SBDs 102-106 and the low supply voltage VSS. In some implementations not shown, the three SBDs 102-106 are implemented by N-type SBDs that share an anode coupled to a control transistor 110 or 110′.

In some implementations not shown, the NAND logic gate 100 has a number of inputs (e.g., 2 inputs, 8 inputs), where the number is distinct from 3. Each input Aᵢ of the NAND logic gate 100 is coupled to a cathode of a respective P-type SBD, and the anode of the respective P-type SBD is coupled to the input of the CMOS inverter 108A. Each P-type SBD can be implemented by a PMOS or NMOS transistor in a counterpart planar CMOS fabrication process integrating no SBDs. As the number of the inputs and P-type SBDs increases, efficiency enhancement attained by replacing transistors with SBDs increases. Referring to FIG. 1B, the inputs A0, A1, and A2 are disposed on a region where the P-type SBDs 102-106 are formed. Compared with transistors formed in the counterpart planar CMOS fabrication process integrating no SBDs, the P-type SBDs 102-106 do not include any gate, channel, source, or drain structures and require a much smaller chip area.

In some implementations, the P-type SBDs 102-106 are formed in an N-well. In some implementations, at least one of the P-type SBDs 102-106 is formed jointly with a subset of the PMOS transistors 110, 112A, and 112B in the N-well. Additionally, in some implementations, one or both of the NMOS transistors 114A and 114B are formed in a P-well that is optionally isolated from the N-well by field oxide or a trench. Further, in some embodiment, a gate of at least one of the PMOS transistor 112A and NMOS transistor 114A extends to at least one of the P-type SBDs 102-106 and is in contact with a P-type semiconductor of the at least one of the P-type SBDs 102-106.

As feature sizes of integrated circuit (IC) on silicon (Si) go down, more complex and diverse electronic functions are integrated on a single silicon die. CMOS IC is currently used as primary semiconductor technology to form very large scale integration (VLSI) logic and static random access memory (SRAM) IC's. An increase in density and complexity of VLSI is mainly due to sustained gradual reduction of a minimum feature size of both semiconductor functional circuit and corresponding metal interconnects. Specifically, a sustained increase in IC density and component count results from development of wafer processing plant equipment, tools and methods, which enables improvements of existing microfabrication techniques and transistor structures and application of new microfabrication techniques and transistor structures. The IC density and component count continue to increase as VLSI technology nodes changed from a planar CMOS fabrication process to a vertical fin-based CMOS fabrication process, e.g., in 2000-2010.

The vertical fin-based CMOS fabrication process is widely applied in the 16-22 nm technology node in which CMOS transistors have been built on fins with increased integration density and complexity. The vertical fin-based CMOS fabrication process is enabled by improvements in established, as well as new types of, semiconductor microfabrication equipment and procedures. For example, self-aligned multiple patterning is applied to increase an effective resolution of photolithography, and atomic layer deposition (ALD) is developed to control the layer deposition of various materials with thicknesses on a nanometer level. Plasma implantation is used to introduce semiconductor doping impurities. In some implementations, two sets of improvements are desirable in technology nodes. First, one desirable improvement of a technology node includes simultaneous increases of an operating speed and a reduction of IC die area and power dissipation. Second, another desirable improvement of a technology node includes using Schottky CMOS technology for both of the planar and vertical fin-based CMOS fabrication processes.

In some implementations, at least a half of transistors that are applied to implement a logic circuit block are replaced with LtSBDs. Each LtSBD has a diode area that is optionally smaller than half of a size of the smallest MOSFET, and therefore, the logic circuit block that integrates the LtSBDs have a smaller block area on a substrate. Additionally, the SBD-based logic circuit block (e.g., using SBDs) have less signal nets or interconnection wires than the transistor-based logic circuit block (e.g., using transistors without any SBDs). For example, the three-input NAND logic gate 100 has a device area of 1.05 μm×0.73 μm (FIG. 1B). When implemented entirely based on transistors, an area of a three-input NAND logic gate is greater than the device area of 1.05 μm×0.73 μm.

Benefits of SCMOS technology are extended to digital circuit, SRAM and non-volatile memory, and analog circuit. SCMOS offers a low-cost solution to keep up with the progress predicted by Moore's Law. SCMOS technology does not rely on size reduction of patterns printed on a semiconductor substrate or improvement of microfabrication steps and equipment. SCMOS technology does not require upgrade or addition of microfabrication equipment, nor does SCMOS technology require implementation of new and more complex silicon wafer processing steps. SCMOS reduces operational expenses of IC manufacturing. In any existing technology node, addition of LtSBDs requires a less extensive impact on existing reliability and quality assurance programs than for creating new transistor structures in a new technology node. Further, SBD-based circuit employs a smaller number of MOSFET device than transistor-based circuit, thereby removing corresponding photomasks and photolithography steps in some situations. Therefore, the total IC manufacturing cost of an established technology node is reduced by integrating SBDs and modifying circuit using SBDs. Various implementations of this application are directed to integration of SBDs in a planar silicone technology node with little or no change to an existing planar CMOS fabrication process.

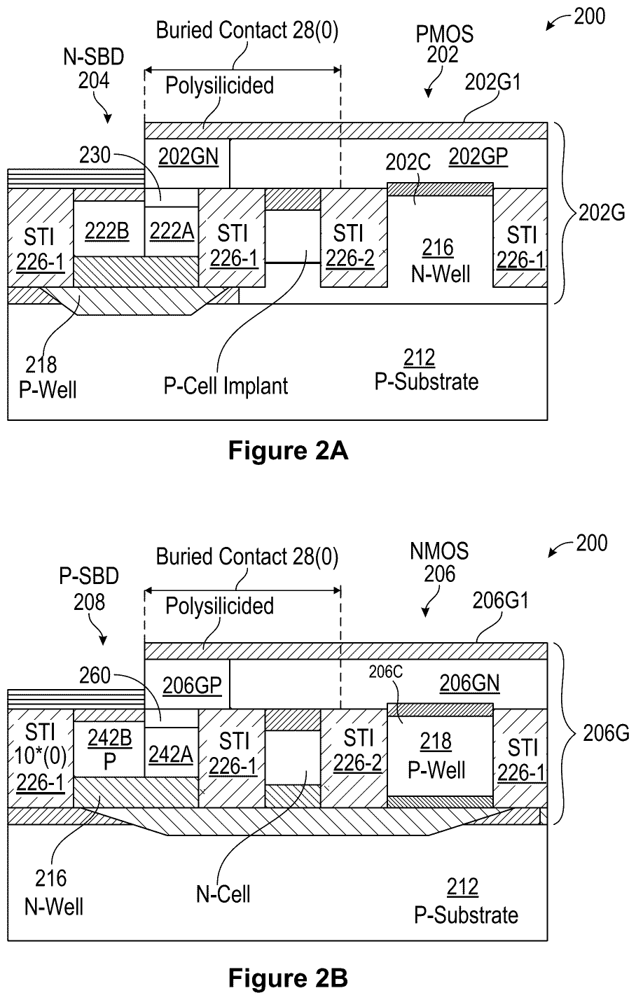

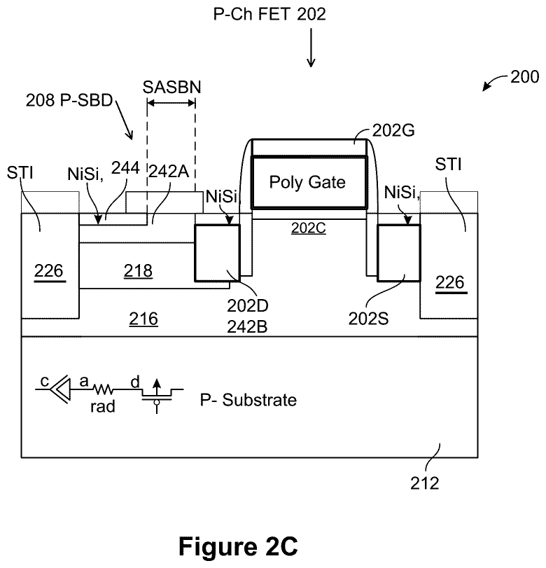

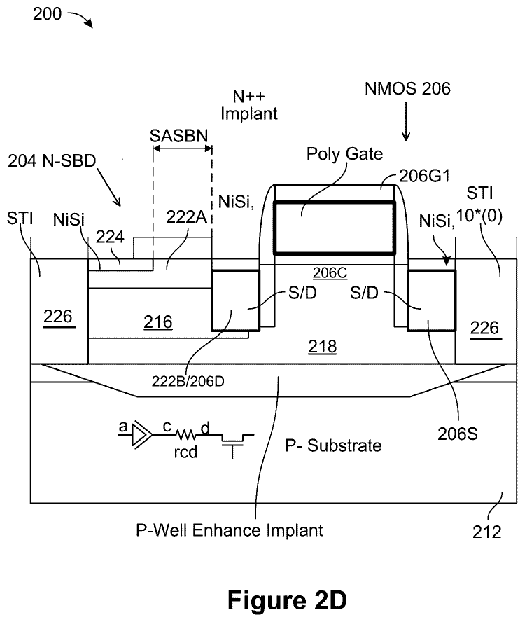

FIG. 2A is a first cross-sectional view of an integrated planar semiconductor device 200 that includes CMOS transistors (e.g., PMOS transistor 202) and complementary SBDs (e.g., N-type SBD 204), in accordance with some implementations. FIG. 2B is a second cross-sectional view of an integrated planar semiconductor device that includes CMOS transistors (e.g., NMOS transistor 206) and complementary SBDs (e.g., P-type SBD 208), in accordance with some implementations. The semiconductor device 200 includes a P-type substrate 212. In an example, the substrate 212 includes a P-Type bulk silicon (e.g., having a resistivity of 10 ohm·cm). In another example, the substrate 212 includes an SOI, including an epitaxial silicon layer formed on a buried oxide. In some embodiments (FIG. 2A), the integrated planar semiconductor device 200 at least includes the PMOS transistor 202 and an N-type SBD 204 formed on the substrate 212. The PMOS transistor 202 includes a gate 202G, a source 202S, and a drain 202D. The N-type SBD 204 joins an N-type semiconductor 222 and a barrier metal 224. The N-type semiconductor 222 includes a first portion 222A and a second portion 222B. In some embodiments (FIG. 2B), the integrated planar semiconductor device 200 at least includes the NMOS transistor 206 and a P-type SBD 208 formed on the substrate 212. The NMOS transistor 206 includes a gate 206G, a source 206S, and a drain 206D. The P-type SBD 208 joins a P-type semiconductor 242 and a barrier metal 244. The P-type semiconductor 242 includes a first portion 242A and a second portion 2r2B.

Referring to FIG. 2A, in some embodiments, a channel 202C of the PMOS transistor 202 is modulated with a P-type channel implant to reduce its threshold voltage value, and has a first doping concentration. This P-type channel implant is applied to form a first portion 242A of a P-type semiconductor 242 of an P-type SBD 208 (FIG. 2B). The first doping concentration of the channel 202C of the PMOS transistor 202 is substantially the same as that of a first portion 242A of a P-type semiconductor 242 of an P-type SBD 208 (FIG. 2B). A doping profile of an extended drain structure 202D of the PMOS transistor is substantially the same as that of a second portion 242B of the P-type semiconductor 242 of the P-type SBD 208 (FIG. 2B). Alternatively, in some embodiments, a channel 202C of the PMOS transistor 202 is modulated with an N-type channel implant (e.g., with N-type dopants) to increase its threshold voltage value. This channel implant is applied to form the first portion 222A of the N-type semiconductor 222 of the N-type SBD 204. A dopant concentration of the channel 202C is distinct from a dopant concentration of the first portion 222A of the N-type SBD 204.

Referring to FIG. 2B, in some embodiments, a channel 206C of the NMOS transistor 206 is modulated with an N-type channel implant to reduce its threshold voltage value, and has a first doping concentration. This N-type channel implant is applied to form a first portion 222A of the N-type semiconductor 222 of the N-type SBD 204 (FIG. 2A). A doping concentration of a first portion 222A of the N-type semiconductor 222 of the N-type SBD 204 (FIG. 2A) is the same as that of a channel 206C of the NMOS transistor 206. A doping profile of the second portion 222B of the N-type semiconductor 222 of the N-type SBD 204 (FIGS. 2A) is substantially the same as an extended drain structure 206D of the NMOS transistor 206. Alternatively, in some embodiments, the channel 206C of the NMOS transistor 206 is modulated with a P-type channel implant to increase its threshold voltage value. This channel implant is applied to form the first portion 242A of the P-type semiconductor 242 of the P-type SBD 208.

Alternatively, in some embodiments, in addition to the channel implant(s), at least one separate SBD implant (e.g., with P-type or N-type dopants) is applied to form the first portion 242A of the N-type SBD 208 or the first portion 222A of the P-type SBD 204. In an example, two separate SBD implants (e.g., with P-type and N-type dopants) are applied to form the first portion 242A of the N-type SBD 208 and the first portion 222A of the P-type SBD 204.

Referring to FIG. 2A, a portion of the gate 202G of the PMOS transistor 202 extends from the PMOS transistor 202 to the N-type SBD 204, substantially in parallel with a surface of the semiconductor device 200. The portion of the gate 202G of the PMOS transistor 202 comes in contact with, and is physically and electrically coupled to the first portion 222A of the N-type semiconductor 222 of the N-type SBD 204. In some embodiments, the portion of the gate includes a polysilicided gate layer 202G1, a P-type polysilicon portion 202GP, and an N-type polysilicon portion 202GN. The entire gate is formed from a single polysilicon layer. The P-type polysilicon portion 202GP and N-type polysilicon portion 202GN share a bottom portion of the same polysilicon layer, except that the polysilicon portions 202GP and 202GN are implanted with P-type dopants and N-type dopants, respectively. The polysilicided gate layer 202G1 includes a top portion of the polysilicon layer and covers both of the polysilicon portions 202GP and 202GN. The polysilicided gate layer 202G1 is formed via a self-aligned silicide process in which a metal thin film is deposited on the polysilicon layer of the gate 202G, source 202S, and drain 202D and annealed and etched to form the polysilicided gate layer 202G1 of the gate 202G and metal silicide contacts of the source 202S and drain 202D. As such, the polysilicided gate layer 202G1 and the P-type polysilicon portion 202GP jointly form the gate 202G of the PMOS transistor 202, and the polysilicided gate layer 202G1 extends onto the N-type polysilicon portion 202GN and comes into contact with the first portion 222A of the N-type semiconductor 222 via the N-type polysilicon portion 202GN.

Referring to FIG. 2B, a portion of the gate 206G of the NMOS transistor 206 extends from the NMOS transistor 206 to the P-type SBD 208. The portion of the gate 206G of the NMOS transistor 206 comes in contact with, and is physically and electrically coupled to the first portion 242A of the P-type semiconductor 242 of the P-type SBD 208. In some embodiments, the portion of the gate includes a polysilicided gate layer 206G1, a P-type polysilicon portion 206GP, and an N-type polysilicon portion 206GN. The P-type polysilicon portion 206GP and N-type polysilicon portion 206GN are implanted with P-type dopants and N-type dopants, respectively. The polysilicided gate layer 206G1 is formed via the self-aligned silicide process. As such, the polysilicided gate layer 206G1 and the N-type polysilicon portion 206GN jointly form the gate 206G of the NMOS transistor 206, and the polysilicided gate layer 206G1 extends onto the P-type polysilicon portion 202GP and comes into contact with the first portion 242A of the P-type semiconductor 242 via the P-type polysilicon portion 206GP.

In some embodiments (FIG. 2A), the N-type polysilicon portion 202GN extended from the gate 202G of the PMOS transistor 202 has a higher doping concentration than the first portion 222A of the N-type semiconductor 222. An N-type diffusion region 230 is formed between the N-type polysilicon portion 202GN and first portion 222A of the N-type semiconductor 222. In some embodiments (FIGS. 2B), the P-type polysilicon portion 206GP extended from the gate 206G of the NMOS transistor 206 has a higher doping concentration than the first portion 242A of the P-type semiconductor 242. A P-type diffusion region 260 is formed between the P-type polysilicon portion 206GP and the first portion 242A of the P-type semiconductor 242.

In some embodiments not shown in the first and second cross-sectional views in FIGS. 2A and 2B, the metal thin film is deposited to cover at least part of the first portions 222A and 242A of the SBDs 204 and 208, jointly with the polysilicon gates 202G and 206G, and patterned to form the barrier metals 224 and 244 of the SBDs 204 and 208, respectively. Additionally, in some embodiments, a junction of the N-type SBD 204 is formed between the barrier metal 224 and the first portion 222A of the N-type semiconductor 222. The second portion 222B of the N-type semiconductor 222 is formed jointly with, and has the same doping profile as, the extended drain structure 206D of the NMOS transistor 206. During the same self-aligned silicide process forming the polysilicided gate layer 202G1 of the gate 202G and the metal silicide contacts of the source 202S and drain 202D, a metal silicide contact is formed on the second portion 222B of the N-type semiconductor 222. The metal thin film is deposited on the second portion 222B of the N-type semiconductor 222, while being deposited on the polysilicon layer of the gate 202G, source 202S, and drain 202D. The metal thin film is annealed and etched to form the metal silicide contact on the second portion 222B of the N-type semiconductor 222, concurrently with forming the polysilicided gate layer 202G1 of the gate 202G and the metal silicide contacts of the source 202S and drain 202D. In some embodiments, each of the source 202S and drain 202D of the PMOS transistor 202 and the second portion 222B of the SBD semiconductor 222 has a distinct silicide contact surface.

In some embodiments, a P-well 218 and an N-well 216 are formed on the substrate 212. Referring to FIG. 2A, in some embodiments, the P-well 218 is adjacent to the N-well 216, and the N-type SBD 204 and the PMOS transistor 202 are located in the P-well 218 and the N-well 216, respectively. Further, in some embodiments, the semiconductor device 200 further includes one or more isolation structures 216-1 or 216-2 disposed between the PMOS transistor 202 and N-type SBD 204 and configured to isolate the PMOS transistor 202 and N-type SBD 204. In some embodiments, the N-type SBD 204 is surrounded and isolated by an isolation structure 216-1, which optionally surrounds additional semiconductor devices formed in the P-well 218. In some embodiments, the PMOS transistor 202 is surrounded and isolated by an isolation structure 216-2, which optionally surrounds additional semiconductor devices formed in the N-well 216. In some embodiments, each isolation structure includes a shallow trench isolation (STI). Alternatively, in some embodiments, each isolation structure 216-1 or 216-2 includes a field oxide region. The field oxide region optionally occupies a larger footprint than a corresponding STI structure 216-1 or 216-2.

FIG. 2C is a third cross-sectional view of an integrated planar semiconductor device 200 that includes CMOS transistors (e.g., PMOS transistor 202) and complementary SBDs (e.g., P-type SBD 208), in accordance with some implementations. FIG. 2D is a fourth cross-sectional view of an example integrated planar semiconductor device 200 that includes CMOS transistors (e.g., NMOS transistor 206) and complementary SBDs (e.g., N-type SBD 204), in accordance with some implementations. In some embodiments, each cross-sectional view in FIG. 2C or 2D corresponds to a different portion of a substrate 212 in that of FIG. 2A or 2B. Referring to FIG. 2C, the integrated planar semiconductor device 200 at least includes a PMOS transistor 202 and a P-type SBD 208, and the PMOS transistor 202 and P-type SBD 208 are formed in an N-well 216 on the substrate 212. In some implementations, the extended drain structure 202D of the PMOS device 202 overlaps the second portion 242B of the P-type semiconductor 242 of the P-type SBD 208. The PMOS transistor 202 is directly coupled to the P-type SBD 208. Referring to FIG. 2C, the integrated planar semiconductor device 200 at least includes an NMOS transistor 206 and an N-type SBD 204, and the NMOS transistor 206 and N-type SBD 204 are formed in a P-well 218 on the substrate 212. In some implementations, the extended drain structure 206D of the NMOS device 206 overlaps the second portion 222B of the N-type semiconductor 222 of the N-type SBD 204. The NMOS transistor 206 is directly coupled to the N-type SBD 204.

Referring to FIG. 2C, the P-type SBD 208 is formed by joining a P-type semiconductor 242 and a barrier metal 244. A first doping concentration of the channel 202C of the PMOS transistor 202 is substantially the same as that of a first portion 242A of the P-type semiconductor 242 of the P-type SBD 208. A doping profile of an extended drain structure 202D of the PMOS transistor 202 is substantially the same as that of a second portion 242B of the P-type semiconductor 242 of the P-type SBD 208. In some embodiments, each of the extended drain structure 202D of the PMOS transistor 202 and the first portion 242A and the second portion 242B of the P-type semiconductor 242 has a distinct silicide contact surface. In some implementations, the first portion 242A of the P-type semiconductor 242 has a first silicide contact surface, and the second portion 242B of the P-type semiconductor 242 has a second silicide contact surface that is separated from the first silicide contact surface by a lateral distance. The lateral distance is greater than a predefined critical dimension CD of a silicide defining mask.

In some implementations not shown, a silicide resistor is formed on the substrate 212. The silicide resistor is distinct from the extended drain structure 206D of the NMOS transistor 206 and the first portion 222A and the second portion 222B of the N-type semiconductor 222. A size of the silicide resistor is much greater than, and therefore, not limited by the critical dimension CD of the silicide defining mask. The source 206S and drain structures and 206D of the NMOS transistor 206 are formed via self-aligned salicidation without being limited by the critical dimension CD of the silicide defining mask. As a result, the predefined critical dimension CD of the silicide defining mask is controlled and defined based on the lateral distance of the N-type SBD 204, which makes the non-critical silicide defining mask in a CMOS fabrication process become a critical mask in an SCMOS fabrication process integrating MOS transistors and SBDs.

In this example shown in FIG. 2D, both the N-type SBD 204 and the NMOS transistor 206 are formed in the P-well 218. Alternatively, in an example, an N-type SBD 204 is located in a first P-well 218, and the NMOS transistor 206 is formed in a second P-well 236 (FIG. 3C) distinct from the first P-well 218. Further, in some implementations (FIG. 3D), an P-type SBD 208 formed in an N-well 238 and by joining an P-type semiconductor 242 and a barrier metal 244. The N-well 238 is isolated from at least one of the first P-well 218 and the second P-well 236 by an isolation structure 226A.

In some implementations, the NMOS transistor 206 includes a first NMOS transistor. The integrated semiconductor device 200 further includes a second NMOS transistor configured to operate with a second N-type channel. The second N-type channel has an alternative doping concentration distinct from the first doping concentration, such that a first threshold voltage of the first NMOS transistor 206 is distinct from a second threshold voltage of the second NMOS transistor. By these means, multiple thresholds are available to form NMOS transistors, and multiple threshold doping concentrations can be selected to form the N-type semiconductor 222 of the N-type SBD 204.

In some implementations, the second portion 222B of the N-type semiconductor 222 includes a second region (e.g., a lightly doped region) where a third region (e.g., a heavily doped region) is formed and enclosed. In accordance with the doping profile, the second region has a second doping concentration, and the third region has a third doping concentration greater than the second doping concentration. The second doping concentration of the second portion 222B is greater than the first doping concentration of the first portion 222A.

FIGS. 3A and 3B are two distinct cross-sectional views 310 and 320 of an example integrated semiconductor device 200 including a PMOS transistor 202 and an N-type SBD 204 in accordance with some implementations. FIGS. 3C and 3D are two distinct cross-sectional views 340 and 350 of an example integrated semiconductor device 200 including an NMOS transistor 206 and a P-type SBD 208, in accordance with some implementations. The cross-sectional views 310 and 320 correspond to two intersecting lines (e.g., two perpendicular line 120 and 140 in FIG. 1B) on a top surface of a corresponding substrate, so are the cross-sectional views 340 and 350. The integrated semiconductor device 200 integrates the PMOS transistor 202 and N-type SBD 204 on a substrate 212, and the integrated semiconductor device 200 integrates the NMOS transistor 206 and P-type SBD 208 on a substrate 214. In some embodiments, the gate of the NMOS transistor 206 (e.g., corresponding to the NMOS transistor 114A in FIG. 1A) extends along the first line 120 to reach the P-type SBD 208 (e.g., corresponding to any of the P-type SBDs 102-106 in FIG. 1A), and the source 206S, gate 206G, and drain 206D of the NMOS transistor 206 are arranged along the second line 140.

In the integrated semiconductor device 200, the PMOS transistor 202 is formed in a first N-well 216, and the N-type SBD 204 is formed in a first P-well 218. The N-type SBD 204 joins an N-type semiconductor 222 and a barrier metal 224 (i.e., an anode). The first P-well 218 and N-well 216 are optionally connected to each other. An isolation structure 226 (e.g., 226A) is optionally formed between the first P-well 218 and N-well 216 to enhance electrical isolation between the PMOS transistor 202 and N-type SBD 204. The isolation structure 226A is located between the P-well 218 and N-well 216, and includes a field oxide region or an STI trench. In some implementations, an isolation structure 226 (e.g., 226B) is used at an edge of the N-well 216 or P-well 218. In some implementations, an isolation structure 226 (e.g., 226C) is used within a respective one of the N-well 216 and P-well 218 to separate two electrical structures (e.g., the N-type SBD 204 and a well contact 228). Conversely, in the integrated semiconductor device 200, the NMOS transistor 206 is formed in a second P-well 236, and the P-type SBD 208 is formed in a second N-well 238. The P-type SBD 208 joins a P-type semiconductor 242 and a barrier metal 244 (i.e., a cathode). The second P-well 236 is distinct from the first P-well 218, and the second N-well 238 is distinct from the second N-well 216. The second P-well 236 and N-well 238 are optionally connected to each other. An isolation structure 226A is formed in a connecting region of the second P-well 236 and N-well 238 to enhance electrical isolation between the NMOS transistor 206 and P-type SBD 208.

The well contact 228 of the first P-well 218 is a combination of a first P-type portion 228A and a second P-type portion 228B, and the P-type portions 228A and 228B are formed with the first portion 242A and second portion 242B of the P-type semiconductor 242 of the P-type SBD 208, respectively. Stated another way, the P-type portions 228A and 228B are formed with the P-type channel 202C and extended drain structure of the PMOS transistor 202, respectively. The second portion 228B is formed in the first P-type portion 228A of the well contact 228 and has a distinct silicide contact surface. The well contact 248 of the second N-well 238 is a combination of a first N-type portion 248A and a second portion 248B, and the N-type portions 248A and 248B are formed with the first portion 222A and second portion 222B of the N-type semiconductor 222 of the N-type SBD 204, respectively. Stated another way, the N-type portions 248A and 248B are formed with the N-type channel 206C and extended drain structure 206D of the NMOS transistor 206, respectively. The second portion 248B is formed in the first N-type portion 248A of the well contact 248 and has a distinct silicide contact surface.

In some implementations, the substrates 212 and 214 are different portions of a silicon wafer processed by a common planar CMOS fabrication process, and separated from the silicon wafer after the planar CMOS fabrication process is completed. Optionally, the substrates 212 and 214 form a single substrate. Optionally, the substrates 212 and 214 are separate from each other. The PMOS transistor 202 has a P-type channel 202C and an extended drain structure 202D. The NMOS transistor 206 has an N-type channel 206C and an extended drain structure 206D. The N-type semiconductor 222 of the N-type SBD 204 has a first portion 222A forming an N-type diffusion tub and a second portion 222B sitting in the N-type diffusion tub of the first portion 222A. The P-type semiconductor 242 of the P-type SBD 208 has a first portion 242A forming a P-type diffusion tub and a second portion 242B sitting in the P-type diffusion tub of the first portion 242A.

The first portion 242A of the P-type semiconductor 242 of the P-type SBD 208 is formed jointly with, and has the same doping concentration as, the P-type channel 202C of the PMOS transistor 202. The second portion 242B of the P-type semiconductor 242 of the P-type SBD 208 is formed jointly with the extended drain structure 202D of the PMOS transistor 202. Distinct silicide contact surfaces for the extended drain structure 202D of the PMOS transistor 202 and the first portion 242A and the second portion 242B of the P-type semiconductor 242 of the P-type SBD 208 are formed concurrently. Additionally, the first portion 222A of the N-type semiconductor 222 of the N-type SBD 204 is formed jointly with and has the same doping concentration with the N-type channel 206C of the NMOS transistor 206. The second portion 222B of the N-type semiconductor 222 of the N-type SBD 204 is formed jointly with the extended drain structure 206D of the NMOS transistor 206. Distinct silicide contact surfaces for the extended drain structure 206D of the NMOS transistor 206 and the first portion 222A and the second portion 222B of the N-type semiconductor 222 of the N-type SBD 204 are formed concurrently. In some implementations, the distinct silicide contact surfaces for the extended drain structures of the PMOS transistor 202 and NMOS transistor 206, the first and second portions of the N-type semiconductor 222 of the N-type SBD 204, and the first and second portions of the P-type semiconductor 242 of the P-type SBD 208 are patterned and formed concurrently, e.g., using a single contact photomask (also called a salicide defining mask).

After the distinct silicide contact surfaces are opened using the single contact photomask, a layer of metallic material is deposited to fill contact holes formed on the distinct silicide contact surfaces of the PMOS transistor 202, NMOS transistor 206, P-type SBD 208, and/or N-type SBD 204. In some embodiments, the layer of metallic material is patterned to provide a drain access 202DA coupled to the silicide contact surface of the extended drain structure 202D of the PMOS transistor 202, an anode access 242C coupled to the silicide contact surface of the second portion 242B of the P-type semiconductor 242 of the P-type SBD 208, the barrier metal 244 coupled to the silicide contact surface of the first portion 242A of the P-type semiconductor 242 of the P-type SBD 208. The layer of metallic material is also patterned to provide a drain access 206DA coupled to the silicide contact surface of the extended drain structure 206D of the NMOS transistor 206, a cathode access 222C coupled to the silicide contact surface of the second portion 222B of the N-type semiconductor 222 of the N-type SBD 204, the barrier metal 224 coupled to the silicide contact surface of the first portion 222A of the N-type semiconductor 222 of the N-type SBD 204.

Each and every functional portion of an SBD 204 or 208 corresponds to a counterpart portion in a transistor. Specifically, a first interconnect layer of the transistor corresponds to a metal layer of the SBD, and a transistor channel having threshold voltage enhancement doping corresponds to a semiconductor portion (e.g., 222A and 242A) of the SBD, while an extended drain structure of the transistor is reconfigured to provide an ohmic contact with the semiconductor portion of the SBD. Although the functional portions of the SBD 204 or 208 already exist in a CMOS fabrication process, a CMOS technology node (e.g., 0.350 μm or lower) is implemented based on at least a self-aligned silicidation (SAS) photomask, i.e., a salicide defining mask, and the SAS photomask is modified to integrate the SBD. In the CMOS fabrication process, the SAS photomask is used to define one or more resistors and has a critical dimension that defines a minimum feature size of the one or more resistors. This critical dimension is greater than critical dimensions of a set of other photomasks (e.g., those defining gate, metal contacts). The SAS photomask allows relaxed tolerances of feature widths and spaces to be printed on a semiconductor substrate. In an example, the critical dimension of the SAS photomask exceeds a critical line such that the SAS photomask is labelled as non-critical. In various implementations of this application, this SAS photomask is changed to a critical mask having a small critical dimension (e.g., less than a predefined critical threshold) for the purposes of integrating the SBDs in the CMOS fabrication process.

Each CMOS technology node has a most critical photomask whose critical dimension is the smallest among all photomasks used in the technology node, and the most critical photomask is a gate photomask defining gates of CMOS transistors formed in the technology node. SCMOS technology integrates LtSBDs in the CMOS technology node and is applied in VLSI applications. The SCMOS technology builds P and N LtSBDs, and each LtSBD occupies a smaller area than a diode-connected counterpart transistor. Each LtSBD is formed on a device active area (i.e., a diffusion tub), and the device active area is formed directly on a respective well depending on a corresponding circuit function and electrical isolation requirements. Each LtSBD includes a barrier metal making contact with a lightly doped semiconductor surface having an impurity concentration of 1015-1018 atoms/cm3. The lightly doped semiconductor surface is doped with arsenic (As), phosphorus (P), or antimony (Sb), Boron (B), preferably according to a retrograde profilc.

Examples of the barrier metals 224 and 244 include, but are not limited to, Nickel Silicide (NiSi), Titanium Silicide (TiSi), or Cobalt Silicide (CoSi₂). Other materials is optionally applied as the barrier metal when a surface is shallowly doped with impurity atoms of metal materials or coated with a thin layer of metal material (e.g., Nickel, Nickel Silicide, Cobalt, Cobalt Silicide, and the like). Specifically, a barrier metal (e.g., Co, Ti) is combined with well doping and transistor threshold adjustment implantations, thereby forming the Nickel Silicide (NiSi), Titanium Silicide (TiSi), or Cobalt Silicide (CoSi2). The LtSBDs can be built with the necessary electrical characteristics to operate with a set of MOSFETs in an SCMOS circuit application. Further, in some implementations, each P-type or N-type SBD has a respective Schottky barrier height voltage that is in a range of Schottky barrier height voltage. The respective Schottky barrier height voltage varies with a temperature of the respective SBD. In some implementations, an SBD is separated from an immediately adjacent SBD or transistor by a trench. Ion implantation is optionally applied to adjust a doping concentration of the diffusion tub or device active area of the SBD, thereby suppressing a reverse bias current of the SBD below a leakage current tolerance.

Referring to FIG. 3B, in some implementations, a PMOS transistor 202 is formed in a first N-well 216 and configured to operate with an P-type channel 202C. Further, in some implementations, the N-type SBD 204 is located in the P-well (e.g., 218 in FIG. 3B) having an P-well access region 228 (also called well contact 228 optionally including portions 228A and 228B). A doping concentration of the P-type channel of the PMOS transistor 202 is equal to that of a first portion 228A of the P-well access region 228. A doping profile of an extended drain structure of the PMOS transistor 202 matches that of a second P-type portion 228B of the P-well access region 228. The second P-type portion 228B of the P-well access region 228 is formed in the first portion 228A of the P-well access region 228 and has a distinct silicide contact surface. The first and second P-type portions 228A and 228B of the P-well access region 228 jointly provide a low-resistance path for the P-well 218.

In some implementations, the integrated semiconductor device 200 further includes an P-type SBD 208 formed in a second N-well 238. The P-type SBD 208 is formed by joining an P-type semiconductor 242 and a barrier metal 244. The first N-well 216 and the second N-well 238 are merged into a single N-well 216. Alternatively, in some implementations, the integrated semiconductor device 200 further includes a P-type SBD 208 formed in a second N-well 238. The first N-well 216 is distinct from the second N-well 238.

FIGS. 4A and 4B are two distinct cross-sectional views 410 and 420 of another example integrated semiconductor device 200 including an NMOS transistor 206 and an N-type SBD 204 in a P-well 218, in accordance with some implementations. The N-type SBD 204 joins an N-type semiconductor 222 and a barrier metal 224 (e.g., a metal anode). A first doping concentration of the N-type channel 206C of the NMOS transistor 206 is substantially the same as that of a first portion 222A of the N-type semiconductor 222 of the N-type SBD 204. A doping profile of an extended drain structure 206D of the NMOS transistor 206 is substantially the same as that of a second portion 222B of the N-type semiconductor 222. Each of the extended drain structure 206D of the NMOS transistor 206 and the first portion 222A and the second portion 222B of the N-type semiconductor 222 has a distinct silicide contact surface. In some embodiments, the N-type SBD 204 includes two SBDs having separate anodes 204A-1 and 204A-2 and a common cathode 204C. The barrier metal 224 is divided to be included in the two SBDs, so is the first portion 222A of the N-type semiconductor 222. Alternatively, in some embodiments, each of the barrier metal 224 and the first portion 222A of the N-type semiconductor 222 partially surrounds the second portion 222B of the N-type semiconductor 222, and the N-type SBD 204 includes a single SBD independently of whether the anodes 204A-1 and 204A-2 are separate or connected.

FIGS. 4C and 4D are two distinct cross-sectional views 440 and 450 of another example integrated semiconductor device 200 including a PMOS transistor 202 and a P-type SBD 208 in an N-well 216, in accordance with some implementations. The cross-sectional views 440 and 450 correspond to two intersecting lines (e.g., two perpendicular line 120 and 140 in FIG. 1B) on a top surface of a corresponding substrate. In some embodiments, the gate of the PMOS transistor 202 (e.g., corresponding to the PMOS transistor 112A in FIG. 1A) extends along the first line 120 to reach the P-type SBD 208 (e.g., corresponding to any of the P-type SBDs 102-106 in FIG. 1A), and the source 202S, gate 202G, and drain 202D of the PMOS transistor 202 are arranged along the second line 140.

The P-type SBD 208 joins a P-type semiconductor 242 and a barrier metal 244 (e.g., a metal cathode). A first doping concentration of the P-type channel 202C of the PMOS transistor 202 is substantially the same as that of a first portion 242A of the P-type semiconductor 242 of the P-type SBD 208. A doping profile of an extended drain structure 202D of the PMOS transistor 202 is substantially the same as that of a second portion 242B of the P-type semiconductor 242. Each of the extended drain structure 202D of the PMOS transistor 202 and the first portion 242A and the second portion 242B of the P-type semiconductor 242 has a distinct silicide contact surface. In some embodiments, the P-type SBD 208 includes two SBDs having separate cathodes 208C-1 and 208C-2 and a common anode 208A. The barrier metal 244 is divided to be included in the two SBDs, so is the first portion 242A of the P-type semiconductor 242. Alternatively, in some embodiments, each of the barrier metal 244 and the first portion 242A of the P-type semiconductor 242 partially surrounds the second portion 242B of the P-type semiconductor 242, and the P-type SBD 208 includes a single SBD independently of whether the anodes 208C-1 and 208C-2 are separate or connected.

In some implementations, the first portion 242A of the P-type semiconductor 242 has a first silicide contact surface, and the second portion 242B of the P-type semiconductor has a second silicide contact surface that is separated from the first silicide contact surface by a lateral distance l₂. The lateral distance l₂ is greater than a predefined critical dimension CD of a silicide defining mask.

In some implementations, the integrated semiconductor device 200 includes a silicide resistor that is formed on the substrate 212 and distinct from the extended drain structure 202D of the PMOS transistor 202 and the first portion 242A and the second portion 242B of the P-type semiconductor 242. A size of the silicide resistor is much greater than, and therefore, not limited by the critical dimension CD of the silicide defining mask. The source 202S and drain structure 202D of the PMOS transistor 202 are formed via self-aligned salicidation without being limited by the critical dimension CD of the silicide defining mask. As a result, the predefined critical dimension CD of the silicide defining mask is controlled and defined based on the lateral distance l₁ or l₂ of the P-type SBD 208, which makes the non-critical silicide defining mask in the CMOS fabrication process become a critical mask in the SCMOS fabrication process integrating MOS transistors and SBDs.

In some implementations, the PMOS transistor 202 includes a first PMOS transistor. The integrated semiconductor device 200 includes a second PMOS transistor configured to operate with a second P-type channel. The second P-type channel has an alternative doping concentration distinct from the first doping concentration, such that a first threshold voltage of the first PMOS transistor 202 is distinct from a second threshold voltage of the second PMOS transistor.

In some implementations, the second portion 242B of the P-type semiconductor 242 includes a second region (e.g., a lightly-doped region) where a third region (e.g., a heavily-doped region) is formed and enclosed. In accordance with the doping profile, the second region has a second doping concentration, and the third region has a third doping concentration greater than the second doping concentration. The second doping concentration of the second region is greater than the first doping concentration of the first portion 242A.

In some implementations shown in FIGS. 4A-4D, both the P-type SBD 208 and the PMOS transistor 202 are formed in an N-well 216. Alternatively, in some implementations shown in FIGS. 3A-3D, the P-type SBD 208 is located in a first N-well 238, and the PMOS transistor 202 is formed in a second N-well 216 distinct from the first N-well 238. Further, in some implementations, the integrated semiconductor device 200 further includes an N-type SBD 204 formed in a P-well 218 and by joining an N-type semiconductor 222 and a barrier metal 224, where the P-well 218 is isolated from at least one of the first N-well 238 and the second N-well 216 by an isolation structure 226A (e.g., field oxide or STI trench).

In some implementations, referring to FIGS. 3A and 4C, the P-type SBD 208 is located in an N-well 216 having an N-well access region 248. A doping concentration of the channel 206C of the NMOS transistor 206 is equal to that of a first N-type portion 248A of the N-well access region 248. A doping profile of an extended drain structure 206D of the NMOS transistor 206 matches that of a second portion 248B of the N-well access region 248. The second portion 248B of the N-well access region 248 is formed in the first N-type portion 248A of the N-well access region 248, and has a distinct silicide contact surface. The first and second N-type portions 248A and 248B of the N-well access region 248 jointly provide a low-resistance path for the N-well 216. In some implementations not shown, an N-well 238 has an N-well access region 248. In some implementations, referring to FIGS. 3C and 4A, an P-well 236 or 216 has a P-well access region 228. A doping concentration of the channel 202C of the PMOS transistor 202 is equal to that of a first P-type portion 228A of the P-well access region 228. A doping profile of an extended drain structure 202D of the PMOS transistor 202 matches that of a second portion 228B of the P-well access region 228. The second portion 228B of the P-well access region 228 is formed in the first P-type portion 228A of the P-well access region 228, and has a distinct silicide contact surface. The first and second P-type portions 228A and 228B of the P-well access region 228 jointly provide a low-resistance path for the P-well 236 or 218.

FIGS. 4E and 4F are cross-sectional views 460 and 470 of two example integrated semiconductor devices 200 each including an NMOS transistor 206 and an N-type SBD 204-1 in a P-well 218, in accordance with some implementations. In some implementations, the extended drain structure 206D of the NMOS device 206 overlaps the second portion 222B of the N-type semiconductor 222 of the N-type SBD 204-1. A drain of the NMOS 206 is electrically coupled to a cathode of the N-type SBD 204-1. In some embodiments, the P-well 218 has a P-well access region 228 providing a low-resistance path for the P-well 218. Further, in some embodiments, the NMOS transistor 206 and the P-well access region 228 are isolated by an isolation structure 226-1 (e.g., a field oxide region or a STI trench structure). Referring to FIG. 4E, in some embodiments, the P-well includes two N-type SBDs 204-1 and 204-2 in the P-well 218. The N-type SBDs 204-1 and 204-2 are isolated by an isolation structure 226-2 (e.g., a field oxide region or a STI trench structure). Referring to FIG. 4F, in some embodiments, the P-well 218 includes a single N-type SBDs 204-1 in the P-well 218. The N-type SBD 204-1 includes two or more metal electrodes 204A-1 and 204A-2 for an anode of the N-type SBD 204-1.

FIGS. 4G and 4H are cross-sectional views 480 and 490 of example integrated semiconductor devices 200 each including a PMOS transistor 202 and a P-type SBD 208-1 in an N-well 216, in accordance with some implementations. In some implementations, the extended drain structure 202D of the PMOS device 202 overlaps the second portion 242B of the P-type semiconductor 242 of the P-type SBD 208-1. A drain of the PMOS 202 acts as an anode of the P-type SBD 208-1. The PMOS 202 corresponds one of the PMOS transistors 110 and 112B, and the P-type SBD 208-1 corresponds to one of the SBDS 102-106 in FIG. 1A. In some embodiments, the N-well 216 has an N-well access region 248 providing a low-resistance path for the N-well 216. Further, in some embodiments, the PMOS transistor 202 and the N-well access region 248 are physically adjacent to each other, and a source 202S of the PMOS transistor 202 and the N-well access region 248 are physically connected via at least a first metal layer 482. In some situations, the first metal layer 482 is electrically coupled to a high power supply VDD. Referring to FIG. 4G, in some embodiments, the N-well includes two P-type SBDs 208-1 and 208-2 in the N-well 216. The P-type SBDs 208-1 and 208-2 are isolated by an isolation structure 226-1 (e.g., a field oxide region or a STI trench structure). Referring to FIG. 4H, in some embodiments, the N-well 216 includes a single P-type SBDs 208-1 in the N-well 216. The P-type SBD 208-1 includes two or more metal electrodes 208C-1 and 208C-2 for a cathode of the P-type SBD 208-1.

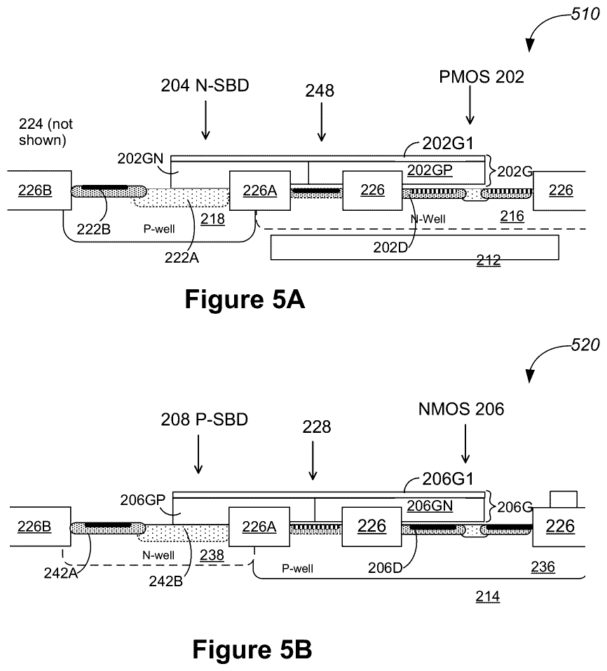

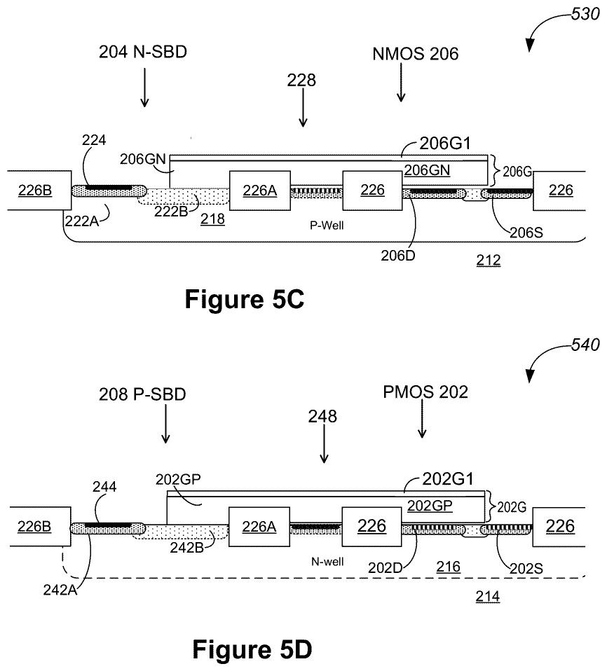

FIG. 5A is a cross-sectional view 510 of an example integrated semiconductor device 200 including a PMOS transistor 202 and an N-type SBD 204 in accordance with some implementations. FIG. 5B is a cross-sectional view 520 of an example integrated semiconductor device 200 including an NMOS transistor 206 and a P-type SBD 208, in accordance with some implementations. FIG. 5C is a cross-sectional view 530 of another example integrated semiconductor device 200 including an NMOS transistor 206 and an N-type SBD 204 in a P-well 218, in accordance with some implementations. FIG. 5D is a cross-sectional view 540 of another example integrated semiconductor device 200 including a PMOS transistor 202 and a P-type SBD 208 in an N-well 216, in accordance with some implementations. In some embodiments, each of the gates 202G and 206G extends above, and is electrically insulated from, a corresponding drain 202D or 206D or a well access region 228 or 248.

Referring to FIG. 5A or 5D, a portion of the gate 202G of the PMOS transistor 202 extends substantially in parallel with a surface of the semiconductor device 200 and from the PMOS transistor 202 to the SBD 204 or SBD 208. The portion of the gate 202G of the PMOS transistor 202 comes in contact with, and is physically and electrically coupled to the second portion of the SBD semiconductor 222 or 242 of the SBD 204 or 208. In some embodiments, the portion of the gate includes a polysilicided gate layer 202G1, a P-type polysilicon portion 202GP, and an N-type polysilicon portion 202GN. Alternatively, in some embodiments, the portion of the gate includes a polysilicided gate layer 202G1 and an N-type polysilicon portion 202GN. The entire gate is formed from a single polysilicon layer. Referring to FIG. 5A, in some embodiments, the P-type polysilicon portion 202GP and N-type polysilicon portion 202GN share a bottom portion of the same polysilicon layer, except that the polysilicon portions 202GP and 202GN are implanted with P-type dopants and N-type dopants, respectively. Referring to FIG. 5D, in some embodiments, the P-type polysilicon portion 202GP extends from the PMOS 202 to the P-type SBD 208 jointly with the polysilicided gate layer 202G1. The polysilicided gate layer 202G1 includes a top portion of the polysilicon layer and covers the polysilicon portions 202GP and/or 202GN.

Referring to FIG. 5B or 5C, a portion of the gate 206G of the NMOS transistor 206 extends from the NMOS transistor 206 to the SBD 208 or 204, substantially in parallel with the surface of the semiconductor device 200. The portion of the gate 206G of the NMOS transistor 206 comes in contact with, and is physically and electrically coupled to the first portion of the SBD semiconductor 222 or 242 of the SBD 208 or 204. In some embodiments, the portion of the gate includes a polysilicided gate layer 206G1, an N-type polysilicon portion 206GN, and a P-type polysilicon portion 206GP. Alternatively, in some embodiments, the portion of the gate includes a polysilicided gate layer 206G1 and a P-type polysilicon portion 206GP. The entire gate is formed from a single polysilicon layer. The entire gate is formed from a single polysilicon layer. Referring to FIG. 5B, the P-type polysilicon portion 206GP and N-type polysilicon portion 206GN share a bottom portion of the same polysilicon layer, except that the polysilicon portions 206GP and 206GN are implanted with P-type dopants and N-type dopants, respectively. Referring to FIG. 5C, in some embodiments, the N-type polysilicon portion 206GN extends from the NMOS 206 to the N-type SBD 204 jointly with the polysilicided gate layer 206G1. The polysilicided gate layer 206G1 includes a top portion of the polysilicon layer and covers the polysilicon portions 206GP and/or 206GN.

The polysilicided gate layers 202G1 and 206G1 are formed via the self-aligned silicide process in which a metal thin film is deposited on the polysilicon layer of the gates 202G and 206G, sources 202S and 206S, and drains 202D and 206D and annealed and etched to form the polysilicided gate layers of the gates 202G and 206G and metal silicide contacts of the sources 202S and 206S and drains 202D and 206D. Referring to FIG. 5A and 5D, the polysilicided gate layer 202G1 and the P-type polysilicon portion 202GP jointly form the gate 206G of the PMOS transistor 202, and the polysilicided gate layer 202G1 extends onto the polysilicon portions 202GN or 202GP and comes into contact with the first portion of the N-type semiconductor 222 or P-type semiconductor 242, respectively. Referring to FIG. 5B and 5C, the polysilicided gate layer 206G1 and the P-type polysilicon portion 206GP jointly form the gate 206G of the NMOS transistor 206, and the polysilicided gate layer 206G1 extends onto the polysilicon portions 206GP or 206GN and comes into contact with the first portion of the N-type semiconductor 222 or P-type semiconductor 242, respectively.

During the same self-aligned silicide process, the polysilicided gate layers of the gates 202G and 206G and the metal silicide contacts of the sources 202S and 206S and drains 202D and 206D are formed concurrently with metal silicide contacts of the second portion 222B of the N-type semiconductor 222 and the second portion 242B of the P-type semiconductor 242. The metal thin film is deposited on the second portion 222B of the N-type semiconductor 222 and the second portion 242B of the P-type semiconductor 242, while being deposited on the polysilicon layer of the gates 202G and 206G, sources 202S and 206S, and drains 202D and 206D. The metal thin film is annealed and etched to form not only the metal silicide contacts of the transistor sources, transistor drains, and SBD semiconductors, but also the polysilicided gate layers of the transistor gates accessing the SBD semiconductors of the SBDs.

In some embodiments (FIGS. 5A and 5C), the N-type polysilicon portion 202GN or 206GN extended from the gate 202 or 206 has a higher doping concentration than the first portion 222A of the N-type semiconductor 222 of the N-type SBD 204. An N-type diffusion region 230 (not shown) is formed between the N-type polysilicon portion 202GN or 206GN and first portion 222A of the N-type semiconductor 222. In some embodiments (FIGS. 5B and 5D), the P-type polysilicon portion 206GP or 202GP extended from the gate 206 or 202 has a higher doping concentration than the first portion 242A of the P-type semiconductor 242 of the P-type SBD 208. A P-type diffusion region 260 (not shown) is formed between the P-type polysilicon portion 206GP or 202GP and the first portion 242A of the P-type semiconductor 242.

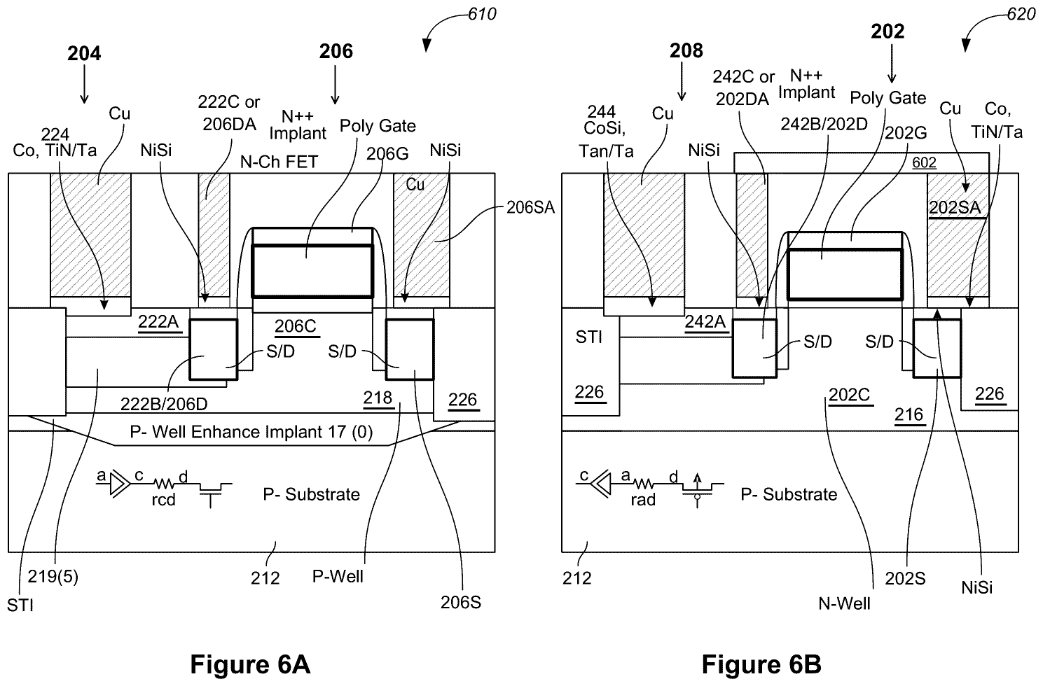

FIGS. 6A and 6B are two distinct cross-sectional views 610 and 620 of an integrated semiconductor device 200 that includes CMOS transistors 202 and 206 and complementary SBDs 204 and 208 and is processed to a first metallic layer in an MOL, in accordance with some implementations. After the FEOL, surfaces of distinct silicide contact surfaces for a gate 202G, source structure 202S, and drain structure 202D of the PMOS transistor 202 are exposed, so are the surfaces of distinct silicide contact surfaces for a gate 206G, source structure 206S, and drain structure 206D of the NMOS transistor 206. Surfaces of the barrier metal 244 and the second portion 242B of the P-type semiconductor 242 of the P-type SBD 208 are exposed, so are the barrier metal 224 and the second portion 222B of the N-type semiconductor 222 of the N-type SBD 204. The first metallic layer is deposited and provide a plurality accesses to the exposed surfaces of distinct silicide contact surfaces. The first metallic layer is a combination of a barrier metal layer (e.g., Nickel, Nickel Silicide, Cobalt, Cobalt Silicide, and the like) and a conductive metal layer (e.g., copper). The barrier metal layer provides barrier metals 224 and 244 for the N-type SBD 204 and P-type SBD 208 and contact enhancing metal on each distinct silicide contact surface for the PMOS transistor 202, N-type SBD 204, NMOS transistor 206, and P-type SBD 208. The conductive metal layer is patterned to a first interconnect layer and provides accesses to an exposed portion of each distinct silicide contact surface for the PMOS transistor 202, N-type SBD 204, NMOS transistor 206, and P-type SBD 208.

In some implementations, referring to FIG. 6A, the NMOS transistor 206 has a drain access 206DA coupled to the silicide contact surface of the extended drain structure 206D of the NMOS transistor 206. The N-type SBD 208 has an anode access 242C coupled to the silicide contact surface of the second portion 242B of the P-type semiconductor 242. The drain access 206DA, cathode access 222C, and barrier metal 224 are formed from a first metallic layer. In some implementations, a source access 206SA is also formed from the first metallic layer. A subset of the source access 206SA, drain access 206DA, cathode access 222C and barrier metal 224 is electrically coupled via the first metallic layer. Further, in some implementations, the drain structure 206D of the NMOS transistor 206 and the second portion 222B of the N-type semiconductor 222 of the N-type SBD 204 optionally overlap with each other, so are the drain access 206DA and cathode access 222C. Conversely, in some implementations, the drain structure 206D and second portion 222B of the N-type semiconductor 222 overlap with each other and are buried under the first metallic layer without any drain or cathode access.

In some implementations, referring to FIG. 6B, the PMOS transistor 202 has a drain access 202DA coupled to the silicide contact surface of the extended drain structure 202D of the PMOS transistor 202. The P-type SBD 208 has an anode access 242C coupled to the silicide contact surface of the second portion 242B of the P-type semiconductor 242. The drain access 202DA, the anode access 242C, and the barrier metal 244 are formed from a first metallic layer. In some implementations, a source access 202SA is also formed from the first metallic layer. A subset of the source access 202SA, drain access 202DA, anode access 242C and barrier metal 244 is electrically coupled via the first metallic layer (e.g., via an interconnect 602). Further, in some implementations, the drain structure 202D of the PMOS transistor 202 and the second portion 242B of the P-type semiconductor 242 of the P-type SBD 208 optionally overlap with each other, so are the drain access 202DA and anode access 242C. Conversely, in some implementations, the drain structure 202D and second portion 242B of the P-type semiconductor 242 overlap with each other and are buried under the first metallic layer without any drain or anode access.

In some implementations not showed, each of silicide contact surfaces of a gate 206G of the NMOS transistor 206 and a gate 202G of the PMOS transistor 202 is at least partially covered by the first metallic layer and accessed by a respective gate access. The respective gate access is optionally coupled to a subset of gates, sources, and drains of CMOS transistors and/or a subset of barrier metals and semiconductors of complementary SBDs formed on the substrate 212 of the integrated semiconductor device 200, e.g., via the first metallic layer and/or any other interconnect layer formed above the first metallic layer.

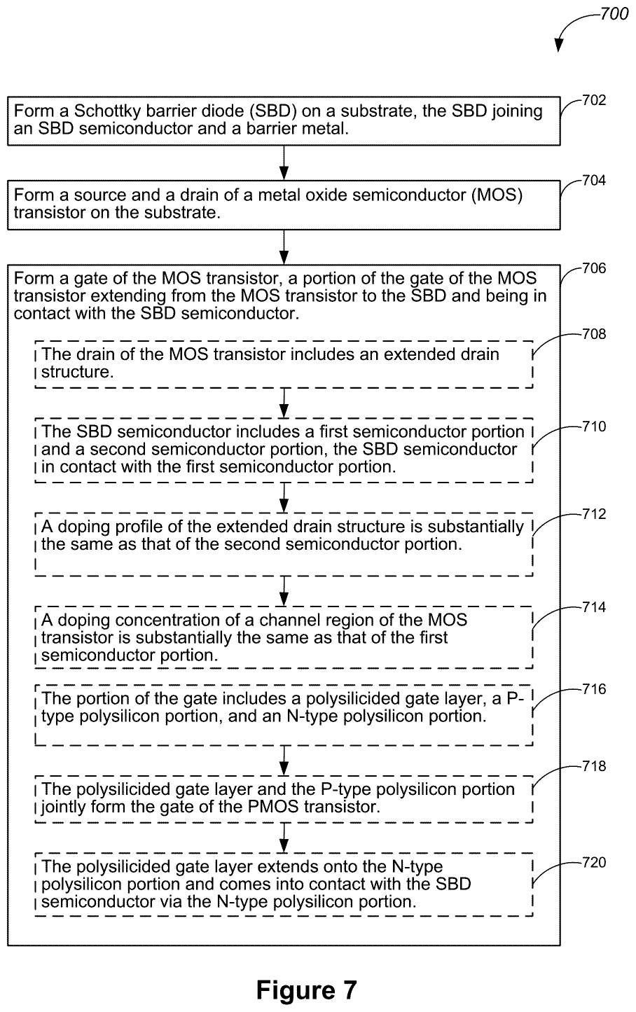

FIG. 7 is a flow diagram of a method 700 of forming an integrated planar semiconductor device 200, in accordance with some implementations. The method 700 includes forming (702) a Schottky barrier diode (SBD) on a substrate. The SBD joins an SBD semiconductor and a barrier metal. The method 700 further includes forming (704) a source and a drain of a metal oxide semiconductor (MOS) transistor on the substrate and forming a gate of the MOS transistor. A portion of the gate of the MOS transistor extends (706) from the MOS transistor to the SBD and is in contact with the SBD semiconductor. In some embodiments, the gate of the MOS transistor includes a polysicided gate layer.

In some implementations, the drain of the MOS transistor includes (708) an extended drain structure. The SBD semiconductor (710) includes a first semiconductor portion and a second semiconductor portion, and the barrier metal is in contact with the first semiconductor portion. A doping profile of the extended drain structure is substantially the same as (712) that of the second semiconductor portion. A doping concentration of a channel region of the MOS transistor is substantially the same as (714) that of the first semiconductor portion. Further, in some implementations, each of the extended drain structure of the MOS transistor and the second semiconductor portion of the SBD semiconductor has a distinct silicide contact surface.

In some implementations, the method 700 includes forming a source access, a drain access, and a SBD semiconductor access from a metallic layer. The source, drain, and SBD semiconductor accesses contact the source, the drain, and the SBD semiconductor on the substrate, respectively.

In some implementations (FIGS. 3A and 3B), the SBD includes an N-type SBD, and the SBD semiconductor includes an N-type semiconductor material. The MOS transistor includes a P-type MOS (PMOS) transistor. The SBD and MOS transistors are located in a P-well and an N-well that is adjacent to the P-well. Further, in some implementations, the portion of the gate includes (716) a polysilicided gate layer, a P-type polysilicon portion, and an N-type polysilicon portion. The polysilicided gate layer and the P-type polysilicon portion jointly form (718) the gate of the PMOS transistor. The polysilicided gate layer extends (720) onto the N-type polysilicon portion and comes into contact with the SBD semiconductor via the N-type polysilicon portion. Additionally, in some implementations, the polysilicided gate layer extends along a first direction perpendicular to a second direction, the P-type polysilicon portion disposed next to the N-type polysilicon portion along the first direction. The source, gate, and drain of the MOS transistor are arranged along the second direction, both the first and second directions being parallel to a surface of the substrate.

In some implementations, the method 700 further includes forming an N-type MOS (NMOS) transistor in the P-well on the substrate, the NMOS transistor including a second gate, a second source, and a second drain. Further, in some embodiments, the method 700 further includes extending the portion of the gate of the MOS transistor from the SBD to the NMOS transistor to merge with a corresponding portion of the second gate.

In some implementations, the SBD includes a first SBD. The method 700 further includes forming a second SBD joining a second SBD semiconductor and a second barrier metal on the substrate and extending the portion of the gate of the MOS transistor from the first SBD to the second SBD to contact the second SBD semiconductor. The first and second SBD are of the same type and formed in the same well.

In some implementations (FIGS. 3C and 3D), the SBD includes an P-type SBD, and the SBD semiconductor includes an P-type semiconductor material. The MOS transistor includes an N-type MOS (NMOS) transistor. The SBD and MOS transistors are located in an N-well and a P-well that is adjacent to the N-well. Further, in some implementations, the portion of the gate includes a polysilicided gate layer, a P-type polysilicon portion, and an N-type polysilicon portion. The polysilicided gate layer and the N-type polysilicon portion jointly form the gate of the NMOS transistor. The polysilicided gate layer extends onto the P-type polysilicon portion and comes into contact with the SBD semiconductor via the P-type polysilicon portion. Additionally, in some implementations, the polysilicided gate layer extends along a first direction perpendicular to a second direction. The P-type polysilicon portion is disposed next to the N-type polysilicon portion along the first direction. The source, gate, and drain of the MOS transistor are arranged along the second direction, both the first and second directions being parallel to a surface of the substrate. In some implementations, the method 700 includes forming a P-type MOS (PMOS) transistor formed in the N-well on the substrate, the PMOS transistor including a second gate, a second source, and a second drain. Further, in some implementations, the method 700 further includes extending the portion of the gate of the MOS transistor from the SBD to the PMOS transistor to merge with a corresponding portion of the second gate.

In some implementations (FIGS. 4A and 4B), the SBD includes an N-type SBD, and the SBD semiconductor includes an N-type semiconductor material. The MOS transistor includes an N-type MOS (NMOS) transistor. The N-type SBD and NMOS transistors are located in the same P-well. The portion of the gate includes a polysilicided gate layer and an N-type polysilicon portion. The polysilicided gate layer and the N-type polysilicon portion jointly form the gate of the NMOS transistor. The polysilicided gate layer and the N-type polysilicon portion extend onto the SBD and comes into contact with the SBD semiconductor via the N-type polysilicon portion.

In some implementations (FIGS. 4C and 4D), the SBD includes an P-type SBD, and the SBD semiconductor includes an P-type semiconductor material. The MOS transistor includes an P-type MOS (PMOS) transistor. The P-type SBD and PMOS transistors are located in the same N-well. The portion of the gate includes a polysilicided gate layer and a P-type polysilicon portion. The polysilicided gate layer and the P-type polysilicon portion jointly form the gate of the PMOS transistor. The polysilicided gate layer and the P-type polysilicon portion extend onto the SBD and comes into contact with the SBD semiconductor via the P-type polysilicon portion.

In some implementations, the portion of the gate of the MOS transistor extends from the MOS transistor to the SBD along a first direction perpendicular to a second direction. The source, gate, and drain of the MOS transistor are arranged along the second direction, both the first and second directions being parallel to a surface of the substrate.

In some implementations, the method 700 further includes forming an field oxide region or a shallow trench isolation (STI) structure. The field oxide region or the STI structure is disposed between the SBD and the MOS transistor and configured to isolate the SBD and MOS transistor.

In some implementations, the SBD and the MOS transistor belong to an X-input NAND logic gate, where X is a positive integer greater than 1.

It should be understood that the particular order in which the operations in each of the above figures have been described are merely exemplary and are not intended to indicate that the described order is the only order in which the operations could be performed. One of ordinary skill in the art would recognize various ways to form an integrated semiconductor device having a MOSFET device and an SBD device on the same substrate as described herein. Additionally, it should be noted that details described with respect to one of the above processes are also applicable in an analogous manner to any other ones of the above processes. For brevity, the analogous details are not repeated.

It will also be understood that, although the terms first, second, etc. are, in some instances, used herein to describe various elements, these elements should not be limited by these terms. These terms are only used to distinguish one element from another. For example, a first type of audio feature can be termed a second type of audio feature, and, similarly, a second type of audio feature can be termed a first type of audio feature, without departing from the scope of the various described implementations. The first type of audio feature and the second type of audio feature are both types of audio features, but they are not the same type of audio feature.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

The foregoing description, for purpose of explanation, has been described with reference to specific implementations. However, the illustrative discussions above are not intended to be exhaustive or to limit the scope of the claims to the precise forms disclosed. Many modifications and variations are possible in view of the above teachings. The implementations were chosen in order to best explain the principles underlying the claims and their practical applications, to thereby enable others skilled in the art to best use the implementations with various modifications as are suited to the particular uses contemplated.

What is claimed is:

1. An integrated planar semiconductor device, comprising:
a substrate;
a Schottky barrier diode (SBD) joining an SBD semiconductor and a barrier metal on the substrate; and
a metal oxide semiconductor (MOS) transistor formed on the substrate and including a gate, a source, and a drain, wherein a portion of the gate of the MOS transistor extends from the MOS transistor to the SBD and is in contact with the SBD semiconductor.

2. The semiconductor device of claim 1, wherein:
the drain of the MOS transistor includes an extended drain structure;
the SBD semiconductor includes a first semiconductor portion and a second semiconductor portion, the barrier metal in contact with the first semiconductor portion;
a doping profile of the extended drain structure is substantially the same as that of the second semiconductor portion; and
a doping concentration of a channel region of the MOS transistor is substantially the same as that of the first semiconductor portion.

3. The semiconductor device of claim 2, wherein each of the extended drain structure of the MOS transistor and the second semiconductor portion of the SBD semiconductor has a distinct silicide contact surface.

4. The semiconductor device of claim 1, further comprising:
a source access, a drain access, and a SBD semiconductor access, wherein the source, drain, and SBD semiconductor accesses are made from a metallic layer and contact the source, the drain, and the SBD semiconductor on the substrate, respectively.

5. The semiconductor device of claim 1, wherein:
the SBD includes an N-type SBD, the SBD semiconductor including an N-type semiconductor material;
the MOS transistor includes a P-type MOS (PMOS) transistor; and
the SBD and MOS transistors are located in a P-well and an N-well that is adjacent to the P-well.

6. The semiconductor device of claim 5, wherein:
the portion of the gate includes a polysilicided gate layer, a P-type polysilicon portion, and an N-type polysilicon portion;
the polysilicided gate layer and the P-type polysilicon portion jointly form the gate of the PMOS transistor; and
the polysilicided gate layer extends onto the N-type polysilicon portion and comes into contact with the SBD semiconductor via the N-type polysilicon portion.

7. The semiconductor device of claim 6, wherein:
the polysilicided gate layer extends along a first direction perpendicular to a second direction, the P-type polysilicon portion disposed next to the N-type polysilicon portion along the first direction; and
the source, gate, and drain of the MOS transistor are arranged along the second direction, both the first and second directions being parallel to a surface of the substrate.

8. The semiconductor device of claim 5, further comprising:
an N-type MOS (NMOS) transistor formed in the P-well on the substrate and including a second gate, a second source, and a second drain.

9. The semiconductor device of claim 8, wherein the portion of the gate of the MOS transistor extends from the SBD to the NMOS transistor and merges with a corresponding portion of the second gate.

10. The semiconductor device of claim 1, the SBD including a first SBD, the semiconductor device further comprising:
a second SBD joining a second SBD semiconductor and a second barrier metal on the substrate, the first and second SBD being of the same type and formed in the same well;
wherein the portion of the gate of the MOS transistor extends from the first SBD to the second SBD and is in contact with the second SBD semiconductor.

11. The semiconductor device of claim 1, wherein:
the SBD includes an P-type SBD, the SBD semiconductor including an P-type semiconductor material;
the MOS transistor includes an N-type MOS (NMOS) transistor; and
the SBD and MOS transistors are located in an N-well and a P-well that is adjacent to the N-well.

12. The semiconductor device of claim 11, wherein:
the portion of the gate includes a polysilicided gate layer, a P-type polysilicon portion, and an N-type polysilicon portion;
the polysilicided gate layer and the N-type polysilicon portion jointly form the gate of the NMOS transistor; and
the polysilicided gate layer extends onto the P-type polysilicon portion and comes into contact with the SBD semiconductor via the P-type polysilicon portion.

13. The semiconductor device of claim 12, wherein:
the polysilicided gate layer extends along a first direction perpendicular to a second direction, the P-type polysilicon portion disposed next to the N-type polysilicon portion along the first direction; and
the source, gate, and drain of the MOS transistor are arranged along the second direction, both the first and second directions being parallel to a surface of the substrate.

14. The semiconductor device of claim 11, further comprising:
a P-type MOS (PMOS) transistor formed in the N-well on the substrate and including a second gate, a second source, and a second drain.

15. The semiconductor device of claim 14, wherein the portion of the gate of the MOS transistor extends from the SBD to the PMOS transistor and merges with a corresponding portion of the second gate.

16. The semiconductor device of claim 1, wherein:
the SBD includes an P-type SBD, the SBD semiconductor including a P-type semiconductor material;
the MOS transistor includes an P-type MOS (PMOS) transistor;
the P-type SBD and PMOS transistors are located in the same N-well;
the portion of the gate includes a polysilicided gate layer and a P-type polysilicon portion;
the polysilicided gate layer and the P-type polysilicon portion jointly form the gate of the PMOS transistor; and
the polysilicided gate layer and the P-type polysilicon portion extend onto the SBD and come into contact with the SBD semiconductor via the P-type polysilicon portion.

17. The semiconductor device of claim 1, wherein:
the SBD includes an N-type SBD, the SBD semiconductor including an N-type semiconductor material;
the MOS transistor includes an N-type MOS (NMOS) transistor;
the N-type SBD and NMOS transistors are located in the same P-well;
the portion of the gate includes a polysilicided gate layer and an N-type polysilicon portion;
the polysilicided gate layer and the N-type polysilicon portion jointly form the gate of the NMOS transistor; and
the polysilicided gate layer and the N-type polysilicon portion extend onto the SBD and comes into contact with the SBD semiconductor via the N-type polysilicon portion.

18. The semiconductor device of claim 1, wherein:
the portion of the gate of the MOS transistor extends from the MOS transistor to the SBD along a first direction perpendicular to a second direction; and
the source, gate, and drain of the MOS transistor are arranged along the second direction, both the first and second directions being parallel to a surface of the substrate.

19. The semiconductor device of c claim 1, further comprising:
an field oxide region or a shallow trench isolation (STI) structure, wherein the field oxide region or the STI structure is disposed between the SBD and the MOS transistor and configured to isolate the SBD and MOS transistor.

20. The semiconductor device of claim 1, wherein the SBD and the MOS transistor belong to an X-input NAND logic gate, where X is a positive integer greater than 1.
